(19) United States
(12) Patent Application Publication
(10) Pub. No.: US 2025/0006791 A1
(43) Pub. Date: Jan. 2, 2025

(54) PEROVSKITE OXIDE FIELD EFFECT TRANSISTOR WITH HIGHLY DOPED SOURCE AND DRAIN

(71) Applicant: Intel Corporation, Santa Clara, CA (US)

(72) Inventors: Rachel A. Steinhardt, Beaverton, OR (US); Kevin P. O'Brien, Portland, OR (US); Dominique A. Adams, Portland, OR (US); Gauri Auluck, Hillsboro, OR (US); Pratyush P. Buragohain, Hillsboro, OR (US); Scott B. Clendenning, Portland, OR (US); Punyashloka Debashis, Hillsboro, OR (US); Arnab Sen Gupta, Hillsboro, OR (US); Brandon Holybee, Portland, OR (US); Raseong Kim, Portland, OR (US); Matthew V. Metz, Portland, OR (US); John J. Plombon, Portland, OR (US); Marko Radosavljevic, Portland, OR (US); Carly Rogan, North Plains, OR (US); Tristan A. Tronic, Aloha, OR (US); I-Cheng Tung, Hillsboro, OR (US); Ian Alexander Young, Olympia, WA (US); Dmitri Evgenievich Nikonov, Beaverton, OR (US)

(73) Assignee: Intel Corporation, Santa Clara, CA (US)

(21) Appl. No.: 18/346,227

(22) Filed: Jul. 1, 2023

(51) Int. Cl. H01L 29/08; H01L 29/06; H01L 29/12; H01L 29/423; H01L 29/51; H01L 29/66; H01L 29/775; H01L 29/78; H01L 29/786

(52) U.S. Cl. CPC H01L 29/0847; H01L 29/0673; H01L 29/12; H01L 29/42392; H01L 29/516; H01L 29/66969; H01L 29/775; H01L 29/78391; H01L 29/785; H01L 29/7869

(57) ABSTRACT

Perovskite oxide field effect transistors comprise perovskite oxide materials for the channel, source, drain, and gate oxide regions. The source and drain regions are doped with a higher concentration of n-type or p-type dopants (depending on whether the transistor is an n-type or p-type transistor) than the dopant concentration in the channel region to minimize Schottky barrier height between the source and drain regions and the source and drain metal contact and contact resistance.

### BACKGROUND

Perovskite materials are a class of materials that have the general chemical formula of ABX₃ and that comprise oxides (X=oxygen). Perovskite materials have a similar crystal structure and can have similar lattice constants. Perovskite materials have shown promise for use in field effect transistors due to the high mobility achievable in some perovskite materials, such as doped stannates (e.g., BaSnO₃, SrSnO₃).

### BRIEF DESCRIPTION OF THE DRAWINGS

FIG. 1 is a cross-sectional view of a first example planar perovskite oxide FET.

FIG. 2 is a cross-sectional view of a second example planar perovskite oxide FET.

FIGS. 3A and 3B are cross-sectional views of an example perovskite oxide FinFET.

FIGS. 4A and 4B are cross-sectional views of an example perovskite oxide stacked gate-all-around FET (GAAFET).

FIGS. 5A and 5B are cross-sectional views of an example forksheet device comprising perovskite oxide FETs.

FIGS. 6A and 6B are cross-sectional views of an example complementary (CFET) device comprising perovskite oxide FETs.

FIGS. 7A-7D illustrate a first example fabrication of a perovskite oxide FET.

FIGS. 8A-8E illustrate a second example fabrication of a perovskite oxide FET.

FIGS. 9A-9D illustrate a third example fabrication of a perovskite oxide FET.

FIG. 10 illustrates a first example perovskite oxide FET fabrication method.

FIG. 11 illustrates a second example perovskite oxide FET fabrication method.

FIG. 12 illustrates a third example perovskite oxide FET fabrication method.

FIG. 13 is a top view of a wafer and dies that may be included in a microelectronic assembly, in accordance with any of the embodiments disclosed herein.

FIG. 14 is a cross-sectional side view of an integrated circuit device that may be included in a microelectronic assembly, in accordance with any of the embodiments disclosed herein.

FIGS. 15A-15D are perspective views of example planar, FinFET, gate-all-around, and stacked gate-all-around transistors.

FIGS. 16A and 16B are perspective and cross-sectional views of example forksheet gate-all-around transistors.

FIGS. 17A and 17B are perspective and cross-sectional views of an example complementary field-effect-transistor (CFET) device.

FIG. 18 is a cross-sectional side view of an integrated circuit device assembly that may include a microelectronic assembly, in accordance with any of the embodiments disclosed herein.

FIG. 19 is a block diagram of an example electrical device that may include a microelectronic assembly, in accordance with any of the embodiments disclosed herein.

### DETAILED DESCRIPTION

Described herein are field effect transistors comprising channel, source, and drain regions comprising perovskite oxides (perovskite oxide FETs). The source and drain regions are more heavily doped than the channel region to provide the advantages of reducing the Schottky barrier between a metal contact and a source or drain region, and reducing parasitic source or drain resistance, which can impact transistor performance. The perovskite oxide FETs disclosed herein can be employed in various transistor types and devices, such as planar FETs (front and/or back gate), FinFETs, gate-all-around FETs (GAAFETs or nanowire, nanoribbon, nanosheet FETs), stacked GAAFETs (ribbonFETs), forksheet devices, and complementary (CFET) devices.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Values and upper and lower range limits preceded by the word “about” include values within 10% of the indicated values and range limits.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims

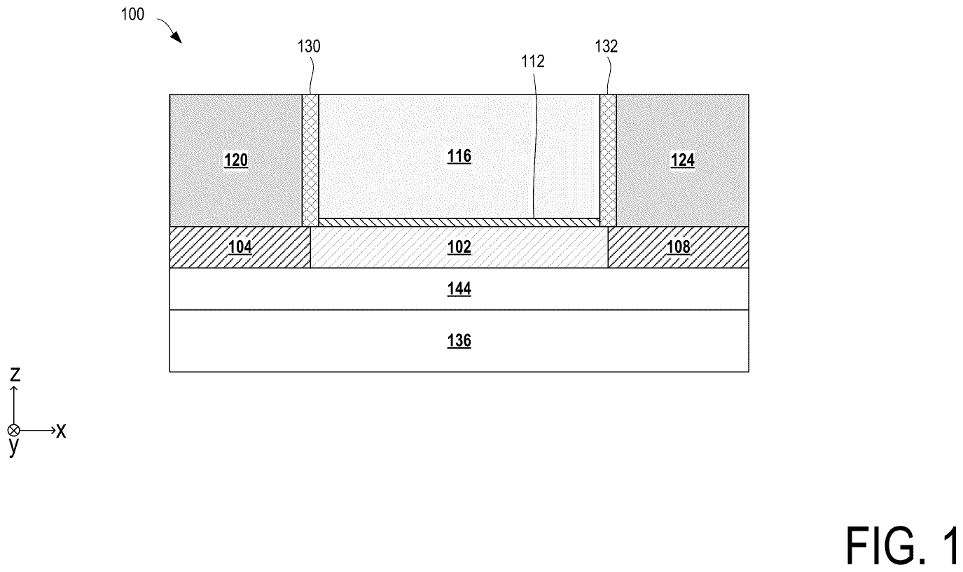

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 1, the gate electrode 116 is located on the channel region 102 with an intervening layer 112.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. The terms “laterally adjacent” and “vertically adjacent” refer to components that are positioned adjacent to each other in a side-by-side or on-top-of arrangement. respectively. For example, with reference to FIG. 1, channel region 102 is positioned laterally adjacent to source and drain regions 104 and 108, respectively, and gate dielectric layer 112 is positioned vertically adjacent to gate electrode 112.

Certain terminology may also be used herein for the purpose of reference only, and thus are not intended to be limiting. For example, terms such as “upper,” “lower,” “above,” “below,” “bottom,” “top”, “lateral”, “vertical”, and “under” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

FIG. 1 is a cross-sectional view of a first example planar perovskite oxide FET. The transistor 100 comprises a channel region 102, source region 104, drain region 108, a gate dielectric layer 112, and a gate electrode 116. The source and drain contact regions 120 and 124 are positioned adjacent to the source and drain regions 104 and 108, respectively. The gate dielectric layer, which may also be a ferroelectric for embodiments where the transistor is a FeFET, is positioned adjacent to the channel region 102 and the gate electrode 116 is located on the gate dielectric layer. The gate dielectric layer 112 is positioned between the gate electrode 116 and the channel region 102. Spacer regions 130 and 132 are positioned between the gate electrode 116 and the gate dielectric layer 112 and the source and drain contact regions 120 and 124, and isolate the source and drain contact regions 120 and 124 from the gate electrode 116 and the gate dielectric layer 112. The source and drain regions 104 and 108 extend underneath a portion of the spacer regions 130 and 132, respectively. The transistor 100 is formed on a substrate or template layer 136 and a buffer layer and/or back gate 144 is positioned between the channel, source, and drain regions 102, 104, and 108 and the substrate or template layer 136. In some embodiments, an additional layer can be positioned between the gate dielectric layer 112 and the channel region 102 to, for example, alleviate strain between gate dielectric layer 112 and the channel region 102. This additional layer can comprise a perovskite oxide and can be an insulating layer when the gate oxide is a ferroelectric in embodiments where the transistor 100 is a negative capacitance FET (NCFET).

The channel region 102, the source region 104, and the drain region 108 comprise a perovskite oxide or doped perovskite oxide, such as barium stannate (BaSnO₃(BSO), a material comprising barium, tin, and oxygen), strontium stannate (SrSnO₃, a material comprising strontium, tin, and oxygen), strontium titanate (SrTiO₃, a material comprising strontium, titanium, and oxygen), (BaₓSr₁₋ₓ)SnO₃, or another suitable perovskite oxide. The source region 104 and the drain region 108 can comprise the same perovskite material. In some embodiments, the channel, source, and drain regions 102, 104, and 108 comprise the same perovskite material. In other embodiments, the source and drain regions 104 and 108 comprise a different perovskite material than the channel region 102. As perovskite materials have a similar crystalline structure and similar lattice constants, the use of perovskites for both the gate dielectric layer and the channel, source, and drain regions can allow for these regions and layers to be epitaxially combined to create interfaces with low defects rates and low levels of trapping of charges. These processing advantages can be more pronounced in perovskite oxides structures where the channel, source, and drain regions and/or the channel region and gate dielectric layer comprise the same perovskite oxide material.

The channel, source, and drain regions 102, 104, and 108 can be doped with one or more dopants, with the source and drain regions 104 and 108 being more heavily doped than the channel region 102. The channel, source, and drain regions 102, 104, and 108 can be doped n-type with lanthanum (La), neodymium (Nd), cesium (Cs), cerium (Cr), yttrium (Y), or vanadium (V), cobalt (Co) or another suitable n-type dopant, or doped p-type with potassium (K), or another suitable p-type dopant. In some embodiments, the source and drain regions can comprise the same dopants. In some embodiments, the channel, source, and drain regions 102, 104, and 108 comprise the same dopants. In other embodiments, the source and drain regions 104 and 108 comprise a different dopant than the channel region 102. In yet other embodiments, the source, drain, and channel regions all have n-type or p-type dopants and in other embodiments, the source and drain region comprise one type of dopant (n-type or p-type) and the channel region comprises the other type of dopant (p-type or n-type).

In some embodiments, the channel region is doped at a level where the dopant replaces one of the constituent atoms of the perovskite oxide (that is, for perovskite oxides having the chemical formula ABO₃, the dopant replaces A or B) at a value of about 3% or less. As used herein, the term “doping concentration” in the context of doping in perovskite oxides refers to the level at which a dopant replaces one of the constituent atoms of a perovskite oxide. For example, in lanthanum-doped barium stannate (Ba₁₋ₓLaₓSnO₃), x is about 0.03 or less and the doping concentration of lanthanum is thus 3% or less. In other embodiments, the doping concentration of the perovskite oxide in the channel region is in the range of about 0.1% to 3%. For example, in lanthanum-doped barium stannate (Ba₁₋ₓLaₓSnO₃), x is in the range of about 0.001 to 0.03 (the doping concentration of lanthanum is in the range of about 0.1% to 3%).

The source and drain contact regions 120 are doped at a higher level than the channel region 102. In some embodiments, the doping concentration in the source or drain perovskite oxides is in the range of about 3% to 15%. In other embodiments, the doping concentration in the source or drain regions is in the range of about 3% to 10%. In yet another embodiment, this doping concentration is in the range of about 3% to 8%. In some embodiments, the doping concentration in any of the source, drain, or channel regions is not uniform throughout the region (a source or drain dopant concentration can have a graded profile in directions toward the substrate and/or the channel) and any doping concentration described or referenced herein can refer to a peak doping (or dopant) concentration in a region. Thus, reference to a source or drain region having greater doping levels than a channel region doping level can refer to a peak doping concentration in the source or drain region being greater than a peak doping concentration in the channel region.

The perovskite oxide materials of the transistor 100 can be grown or otherwise deposited on substrate or template layer 136. In some embodiments, the substrate 136 may include an oxide template material on top of a more typical substrate material, such as silicon. For example, the substrate 136 may include an oxide material layer such as SrTiO₃ (which may also be referred to herein as “STO”) on a silicon-based or similar type of substrate material. A back gate or buffer layer 144 is positioned between the channel, source, and drain regions 102, 104, and 108, and the substrate or template layer 136. If the back gate or buffer layer 144 is implemented as a buffer layer, the layer 144 can include a high-k dielectric material. If the layer 144 is implemented as a back gate region of the perovskite oxide transistor, the layer 144 may be formed from or include SrRuO₃ (which may also be referred to herein as “SRO”), (Sr,Ba)RuO₃, SrIrO₃, (La,Ba)SnO₃, (La,Sr)MnO₃, (La,Ba)CoO₃, LaNiO₃, LaRuO₃, SrVO₃, SrCoO₃, SrMoO₃, or YBa₂Cu₃O₇. In other embodiments, the substrate 136 can comprise any of the materials that can be part of any other substrate described or referenced herein, such as die substrate 1402. In some embodiments, planar perovskite oxide transistors comprising a front gate do not have a back gate or a buffer layer.

The source contact region 120, drain contact region 124, and gate contact region (or gate electrode) 116 can comprise tungsten, cobalt, titanium, gold, aluminum, molybdenum, chromium, nickel, or other suitable metals, including metallic oxides.

The spacer regions 128 and 132 can comprise a suitable nitride or oxide, such as silicon nitride (Si₃N₄), silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, the spacer regions 130 and 132 can comprise strontium titanate (SrTiO₃) or one or more other insulating perovskite oxides.

In some embodiments, the gate dielectric layer 112 can comprise hafnium (IV) oxide (HfO₂), silicon dioxide (SiO₂), barium stannate (BaSnO₃), strontium stannate (SrSnO₃), strontium titanate (SrTiO₃), lanthanum aluminate (LaAlO₃), barium hafnium oxide (BaHfO₃), barium zirconate (BaZrO₃), strontium hafnium oxide (SrHfO₃), lanthanum indium oxide (LaInO₃), lanthanum scandium oxide (LaScO₃), lanthanum lutetium oxide (LaLuO₃), La(LuSc)O₃, magnesium oxide (MgO), or ReScO₃, where Re may be dysprosium (Dy), terbium (Tb), gadolinium (Gd), europium (Eu), samarium (Sm), neodymium (Nd), prascodymium (Pr), cerium (Ce), or lanthanum (La) or another suitable oxide.

In other embodiments, the gate dielectric layer 112 can comprise a ferroelectric perovskite oxide to enable the transistor 100 to be a ferroelectric FET (FeFET) or negative capacitance FET (NCFET) structure. In such embodiments, the gate dielectric layer 112 can comprise barium titanate (BaTiO₃ (BTO), a material comprising barium, titanium, and oxygen), zirconium-doped barium titanate (BaZrₓTi₁₋ₓO₃), calcium-doped barium titanate (Ba₁₋ₓCaₓ)TiO₃, strontium-doped barium titanate (Ba₁₋ₓSrₓTiO₃), calcium and zirconium co-doped barium titanate (Ba₁₋ₓCaₓTi_{1-y}Zr_{y}O₃), hafnium-doped barium titanate (BaHfₓTi₁₋ₓO₃), bismuth ferrite (BiFeO₃ (BFO), a material comprising bismuth, iron, and oxygen), lanthanum-doped bismuth ferrite (Bi₁₋ₓLaₓFeO₃), cobalt-doped bismuth ferrite (BiFe₁₋ₓCoₓO₃), lithium niobate (LiNbO₃, a material comprising lithium, niobium, and oxygen), potassium niobate (KNbO₃, a material comprising potassium, niobium, and oxygen), GdFeO₃ (a material comprising gadolinium, iron, and oxygen), and lanthanum-doped GdFeO₃ (Gd₁₋ₓLaₓFeO₃), or another suitable ferroelectric perovskite material. In other embodiments where the transistor 100 is a FeFET or NCFET, the gate dielectric layer 112 comprises doped HfO₂, wherein HfO₂ is doped with lanthanum, strontium, aluminum, silicon, yttrium, gadolinium, or zirconium.

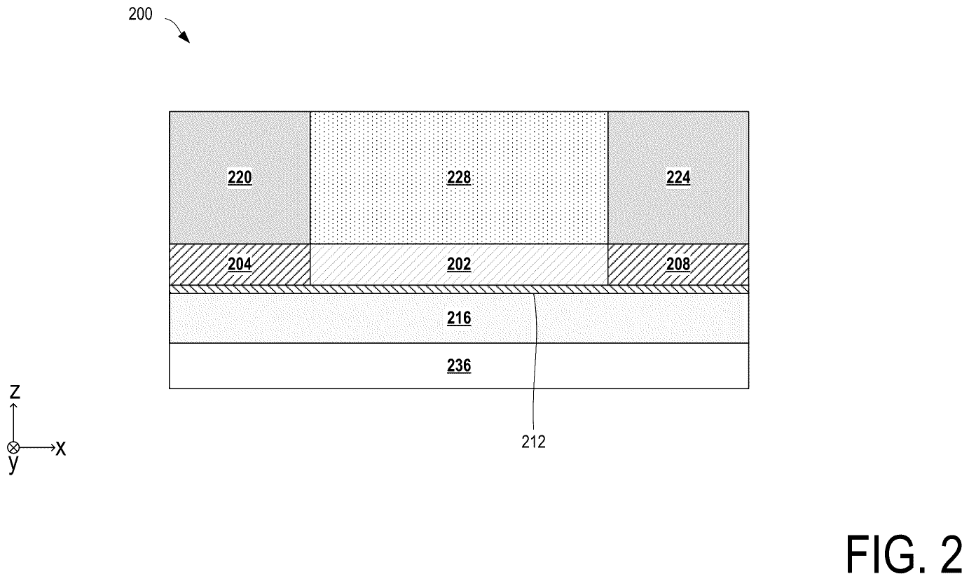

FIG. 2 is a cross-sectional view of a second example planar perovskite oxide FET. The transistor 200 comprises a channel region 202, source region 204, drain region 208, a gate dielectric layer 212, and a gate electrode 216. Source and drain contact regions 220 and 224 are positioned adjacent to the source and drain regions 204 and 208, respectively. The gate dielectric layer 212 is positioned adjacent to the channel region and the gate electrode 216 is located under the gate dielectric layer 212 and between the channel region 202 and the substrate or template layer 236. The gate dielectric layer 212 is positioned between the gate electrode 216 and the channel region 202. The channel region 202, source region 204, and the drain region 208 can comprise any of the perovskite oxide materials, dopants, and dopant concentrations and profiles as the channel region 102, source region 104, and the drain region 108. The substrate or template layer 236 can comprise any of the materials that can comprise the substrate or template layer 136. The source contact region 220, the drain contact region 240, and the gate electrode region 228 can comprise any of the materials that comprise the source contact region 120, the drain contact region 124, and the gate electrode 116. The gate dielectric layer 212 can comprise any of the materials that can comprise the gate dielectric layer 112.

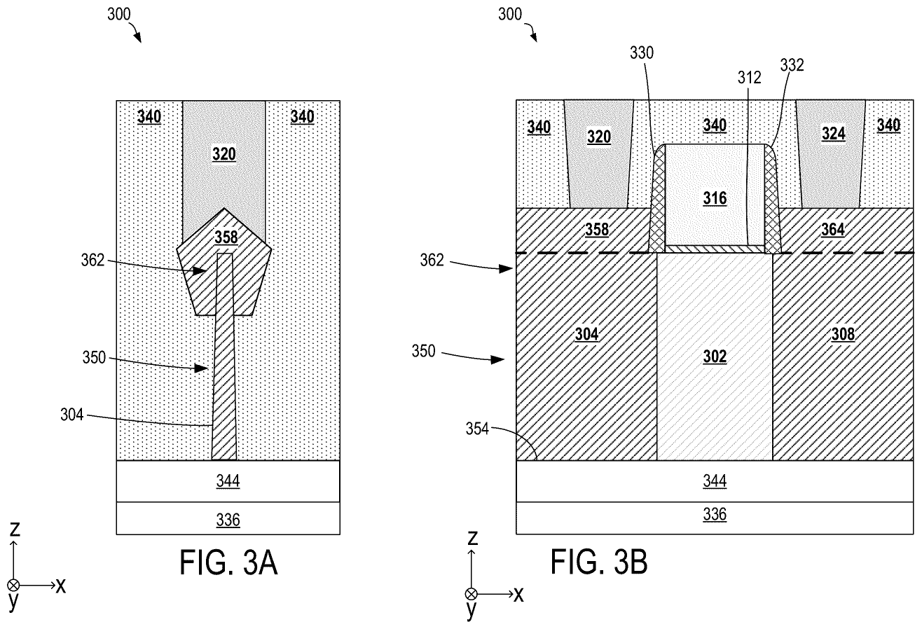

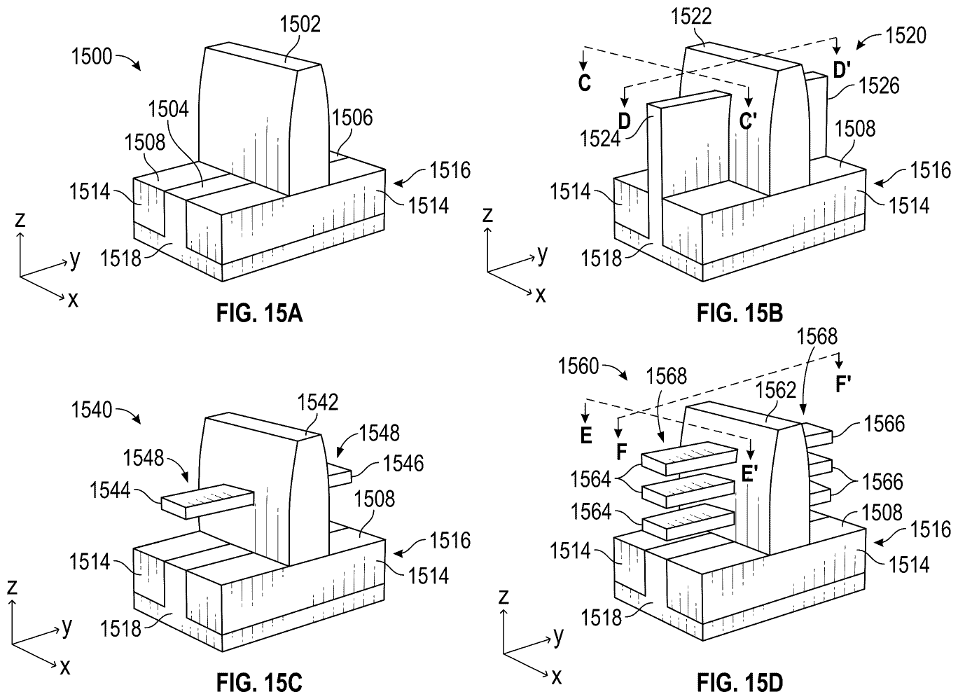

FIGS. 3A and 3B are cross-sectional views of an example perovskite oxide FinFET. The cross-sectional view of FIG. 3A is taken along a line extending through the source and drain of FinFET 300 and is similar to a cross-sectional view of FinFET 1520 taken along the line C-C′ in FIG. 15B. The cross-sectional view of FIG. 3B is taken along a line extending through the source, drain, and gate regions of the FinFET 300 and is similar to a cross-sectional view of FinFET 1520 taken along the line D-D′ in FIG. 15B.

The FinFET 300 comprises a channel region 302, source region 304, drain region 308, a gate dielectric layer 312, and a gate electrode 316. A fin 350 extends upwards from a buffer layer 344 located on a surface 354 of a substrate or template layer 336. The fin 350 comprises the channel region, source, and drain regions 302, 304, and 308. A source region 358 is positioned adjacent to the source region 304 along a first portion of an end 362 of the fin 350 and a drain region 364 is positioned adjacent to the drain region 308 along a second portion of the end 362 of the fin 350. The source and drain regions 358 and 364 can provide a larger source region area for the source and drain contact regions 320 and 324 to contact, respectively. In some embodiments, the source and drain regions 358 and 364 are epitaxially grown. The gate dielectric layer 312 is positioned adjacent to the channel region 302 and the gate electrode 316 is located on the gate dielectric layer 312. The gate dielectric layer 312 wraps around the end 362 of the fin 350. The gate dielectric layer 312 is positioned between the gate electrode 316 and the channel region 302. Spacer regions 330 and 332 are positioned adjacent to the gate electrode 316 and the gate dielectric layer 312. The source and drain regions 304 and 308 extend underneath a portion of the spacer regions 330 and 332, respectively. Dielectric regions 340 are positioned adjacent to the fin 350, the source and drain regions 358 and 364, the source and drain contact regions 320 and 324, and the gate electrode 316. In some embodiments, a FinFET transistor may not have source and drain regions (e.g., 358, 364) that provide a larger area for source and drain contacts to attach to and the source and drain contacts are positioned adjacent to the source and drain portions of the fin (e.g., 304, 308).

The channel region 302, source region 304, and drain region 308 can comprise any of the perovskite oxide materials, dopants, and dopant concentrations and profiles as the channel region 102, source region 104, and the drain region 108. The source region 358 can comprise the same perovskite oxide material and dopant as the source region 304 and the drain region 364 can comprise the same perovskite oxide material and dopant as the drain region 308. The substrate or template layer 336 can comprise any of the materials that can comprise the substrate or template layer 136. The source contact region 320, the drain contact region 324, and the gate electrode region 328 can comprise any of the materials that comprise the source contact region 120, the drain contact region 124, and the gate electrode 116. The gate dielectric layer 312 can comprise any of the materials that can comprise the gate dielectric layer 112. The dielectric regions 340 and the spacer regions 330 and 332 can comprise any of the materials that comprise the spacer regions 130 and 132, respectively.

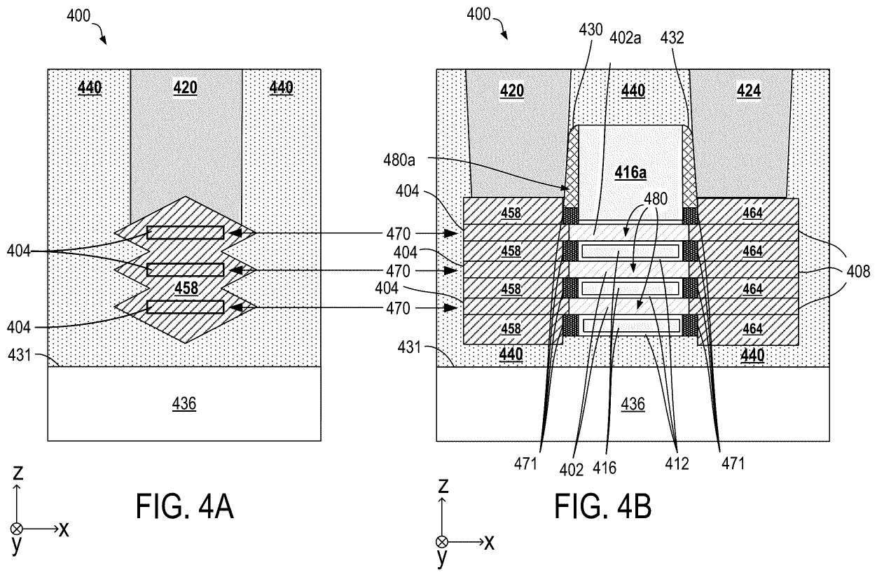

FIGS. 4A and 4B are cross-sectional views of an example perovskite oxide stacked gate-all-around FET (GAAFET). The cross-sectional view of FIG. 4A is taken along a line extending through the source and drain of stacked GAAFET 400 (ribbonFET, or nanosheet, nanowire, nanoribbon FET) and is similar to a cross-sectional view of stacked GAAFET device 1560 taken along the line E-E′ in FIG. 15D. The cross-sectional view of FIG. 4B is taken along a line extending through the source, drain, and gate regions of the stacked GAAFET 400 and is similar to a cross-sectional view of stacked GAAFET 1560 taken along the line F-F′ in FIG. 15D.

The stacked GAAFET 400 comprises layers 470 stacked vertically with respect to a surface 431 of the substrate 436. Each of the layers 470 comprises a channel region 402, a source region 404, and a drain region 408. The stacked GAAFET 400 further comprises gate regions 480. Each gate region 480 comprises a gate dielectric layer 412 and a gate electrode 416. The gate dielectric layer 412 of the top gate region 480a (the gate region positioned furthest from the substrate 436) is positioned between the gate electrode 416a and the channel region 402a positioned furthest from the substrate 436. For the other gate regions 480, the gate dielectric layer 412 encircles the gate electrode 416. In some embodiments, the stacked GAAFET 400 can comprise one layer 470 and the GAAFET is a non-stacked GAAFET in which a single perovskite oxide strip (nanoribbon, nanowire, or nanoribbon) comprises the channel, source, and drain regions of the non-stacked GAAFET.

A source region 458 is positioned adjacent to the source region 404 and a drain region 464 is positioned adjacent to the drain region 408. Source and drain contact regions 420 and 424 are positioned adjacent to source and drain regions 458 and 464, respectively. The source and drain regions 458 and 464 can provide a larger source region area for the source and drain contact regions 420 and 424 to contact to, respectively. In some embodiments, the source and drain regions 458 and 464 are epitaxially grown. Spacer regions 430 and 432 are positioned adjacent to the gate electrode 416 and the gate dielectric layer 412 and spacer regions 471 are positioned between source regions 458 or drain regions 464 and the gate regions 480. The source and drain regions 404 and 408 extend underneath a portion of the spacer regions 430, 432, and 471. Dielectric regions 440 are positioned adjacent to the source and drain regions 458, 464, 404, and 408, the source and drain contact regions 420 and 424, and the topmost and bottommost gate regions 480. In some embodiments, a GAAFET may not have source and drain regions (e.g., 458, 464) that provide a larger area for source and drain contacts to attach to and the source and drain contacts are positioned adjacent to the source and drain portions (e.g., 404, 408) of a perovskite strip (nanoribbon, nanosheet, nanowire) (e.g., 470).

The channel regions 402, source regions 404, and drain regions 408 can comprise any of the perovskite oxide materials, dopants, and dopant concentrations and profiles as the channel region 102, source region 104, and the drain region 108. The source region 458 can comprise the same perovskite oxide material and dopant as the source regions 404 and the drain region 464 can comprise the same perovskite oxide material and dopant as the drain regions 408. The substrate 436 can comprise any of the materials that can comprise the substrate 136. The source contact region 420, the drain contact region 424, and the gate electrode 416 can comprise any of the materials that comprise the source contact region 120, the drain contact region 124, and the gate electrode 116. The dielectric regions 440 and the spacer regions 430, 432, and 471 can comprise any of the materials that comprise the spacer regions 130 and 132, respectively.

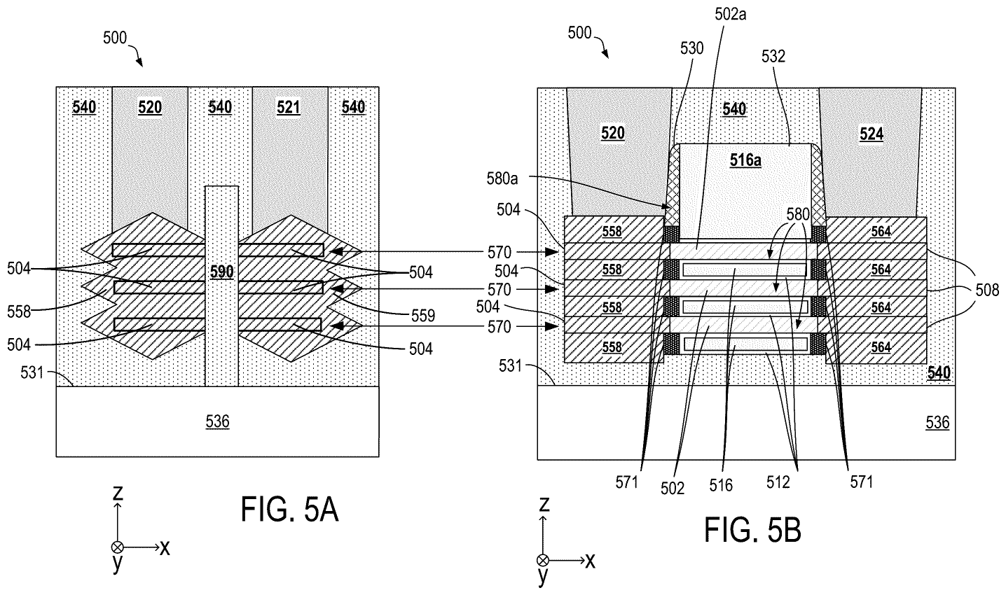

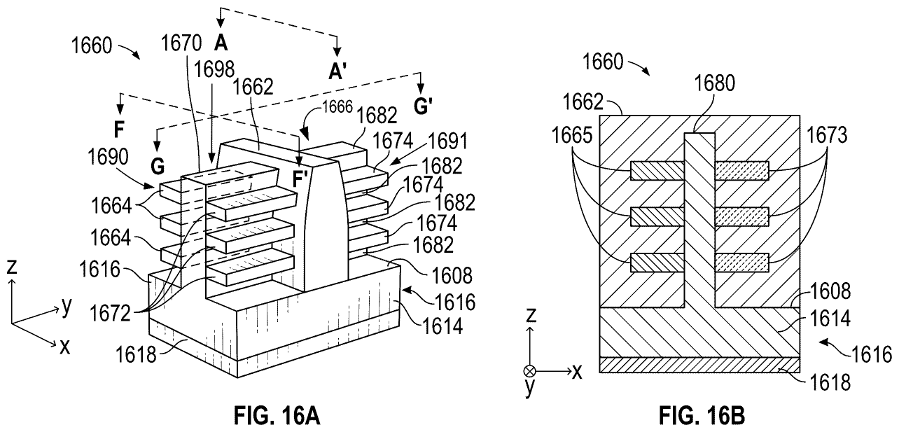

FIGS. 5A and 5B are cross-sectional views of an example forksheet device comprising perovskite oxide FETs. The cross-sectional view of FIG. 5A is taken along a line extending through the source and drain of forksheet device 500 and is similar to a cross-sectional view of the forksheet device 1660 taken along the line F-F′ in FIG. 16A. The cross-sectional view of FIG. 5B is taken along a line extending through the source, drain, and gate regions of one stacked GAAFET of forksheet device 500 and is similar to a cross-sectional view of forksheet device 1660 taken along the line G-G′ in FIG. 16A.

The forksheet device 500 comprises a pair of stacked GAAFETs positioned next to each other, with a dielectric region 590 separating source, drain, and channel regions 504, 508, and 502 of the adjacent GAAFETs. The forksheet device 500 comprises layers 570 stacked vertically with respect to a surface 531 of the substrate 536. Each of the layers 570 comprises a channel region 502, source region 504, and a drain region 508 of one of the stacked GAAFETs. Each GAAFET of the forksheet device 500 further comprises gate regions 580. Each gate region 580 comprises a gate dielectric layer 512 and a gate electrode 516. The gate dielectric layer 512 of the topmost gate region 580a (the gate region positioned furthest from the substrate 536) is positioned between the gate electrode 516a and the channel region 502a positioned furthest from the substrate 536. For the other gate regions 580, the gate dielectric layer 512 encircles the gate electrode 516.

Source regions 558 and 559 are positioned adjacent to the source regions 504 of the first and second stacked GAAFETs of the forksheet device 500, respectively. Drain region 564 and a second drain region (not shown in FIG. 5B) are positioned adjacent to the drain regions 508 of the first and second stacked GAAFETs of the forksheet device 500, respectively. Source contact regions 520 and 521 are positioned adjacent to the source and drain regions 558 and 559, respectively, and drain contact regions 524 and a second drain contact region (not shown in FIG. 5B) are positioned adjacent to a portion of the drain regions 564 and the second drain regions (not shown in FIG. 5B), respectively. These source and drain regions (e.g., 558, 559, 564) can provide a larger source region area for the source and drain contacts (e.g., 520, 521, 524) to contact to, respectively. In some embodiments, these source and drain regions are epitaxially grown. Spacer regions 530 and 532 are positioned adjacent to the gate electrode 516a and the gate dielectric layer 512 and spacer regions 571 are positioned between the source regions 558 or drain regions 564 and the gate regions 580. The source and drain regions 504 and 508 of each GAAFET extend underneath a portion of the spacer regions 530, 532, and 571. Dielectric regions 540 are positioned adjacent to the source and drain regions 558, 559, 564, 504, and 508, the source and drain contact regions 520, 521, and 524, and the topmost and bottommost gate regions 580. In some embodiments, a GAAFET may not have source and drain regions (e.g., 558, 559, 564) that provide a larger area for source and drain contacts to attach to and the source and drain contacts are positioned adjacent to the source and drain portions (e.g., 504, 508) of the layers 570 (nanoribbon, nanowire, nanosheet) of each stacked GAAFET.

The channel regions 502, source regions 504, and drain regions 508 can comprise any of the perovskite oxide materials, dopants, and dopant concentrations and profiles as the channel region 102, source region 104, and the drain region 108. The source regions 558 and 559 can comprise the same perovskite oxide material and dopant as the source regions 504 and the drain region 564 and the second drain region not shown in FIG. 5B can comprise the same perovskite oxide material and dopant as the drain regions 508. The substrate 536 can comprise any of the materials that can comprise the substrate 136. The source contact regions 520 and 521, the drain contact region 524, and the gate electrode 516 can comprise any of the materials that comprise the source contact region 120, the drain contact region 124, and the gate electrode 116. The spacer regions 530, 532, and 571 can comprise any of the materials that comprise the spacer regions 130 and 132, respectively.

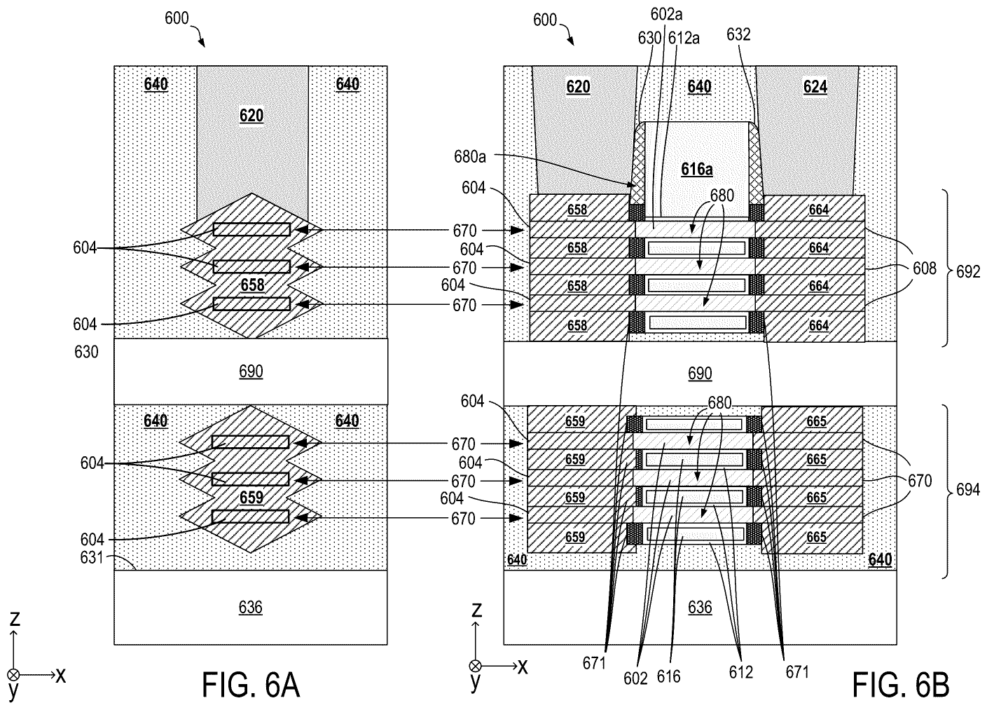

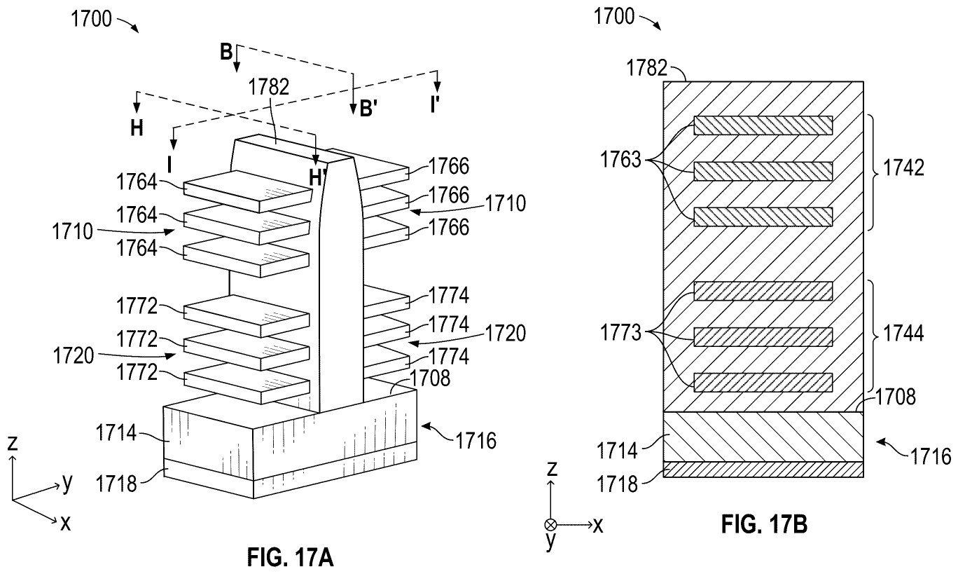

FIGS. 6A and 6B are cross-sectional views of an example complementary (CFET) device comprising perovskite oxide FETs. The cross-sectional view of FIG. 6A is taken along a line extending through the source and drain a CFET device 600 and is similar to a cross-sectional view of the CFET device 1700 taken along the line H-H′ in FIG. 17A. The cross-sectional view of FIG. 6B is taken along a line extending through the source, drain, and gate regions of one of the stacked GAAFETs of CFET device 600 and is similar to a cross-sectional view of CFET device 1700 taken along the line I-I′ in FIG. 17A.

The CFET device 600 comprises a pair of stacked GAAFETs stacked vertically, with a middle dielectric region 690 positioned between a top GAAFET 692 and a bottom GAAFET 694. Each GAAFET in the CFET device comprises layers 670 stacked vertically with respect to a surface 631 of the substrate 636. Each of the layers 670 comprises a channel region 602, source region 604, and a drain region 608 of one of the stacked GAAFETs. Each stacked GAAFET of the CFET device 600 further comprises gate regions 680. Each gate region 680 comprises a gate dielectric layer 612 and a gate electrode 616. For the topmost gate region 680a (the gate region 680 furthest from the substrate 636), the gate dielectric layer 612a is positioned between the gate electrode 616a and the channel region 602a positioned further from the substrate 636. For the other gate regions 680, the gate dielectric layer 612 encircles the gate electrode 616.

Source regions 658 and 659 are positioned adjacent to the source regions 604 of the GAAFETs 692 and 694, respectively. Drain regions 664 and 665 are positioned adjacent to the drain regions 608 of the GAAFETs 692 and 694, respectively. Source and drain contact regions 620 and 624 are positioned adjacent to a portion of the source and drain regions 658 and 664, respectively. The source and drain regions 659 and 665 are contacted by source and drain regions that extend along a length of the y-axis not captured in the cross-sectional view of FIG. 5B and are thus not shown. Source and drain regions 658, 659, 664, and 665 provide a larger source region area for the source and drain contacts (e.g., 620, 624). In some embodiments, these source and drain regions (e.g., 658, 659, 664, 665) are epitaxially grown. Spacer regions 630 and 632 are positioned adjacent to the gate electrode 616 and the gate dielectric layer 612 and spacer regions 671 are positioned between the source region 658 or drain region 664 and the gate regions 680. The source and drain regions 604 and 608 of each GAAFET extend underneath a portion of the spacer regions 630, 632, and 671. Dielectric regions 640 are positioned adjacent to the source and drain regions 658, 659, 664, 604, and 608, the source and drain contact regions 620 and 624, and the topmost and bottommost gate regions 680. In some embodiments, the GAAFETs of a CFET device may not have source and drain regions (e.g., 658, 659, 664, 665) that provide a larger area for source and drain contacts to attach to and the source and drain contacts are positioned adjacent to the source and drain portions of the nanoribbons of each GAAFET.

The channel regions 602, source regions 604, and drain regions 608 can comprise any of the perovskite oxide materials, dopants, and dopant concentrations and profiles as the channel region 102, source region 104, and the drain region 108. The source regions 658 and 659 can comprise the same perovskite oxide material and dopant as the source regions 604 and the drain region 664 and the second drain region not shown in FIG. 6B can comprise the same perovskite oxide material and dopant as the drain regions 608. The substrate 636 can comprise any of the materials that can comprise the substrate 136. The source contact regions 620 and 621, the drain contact region 624, and the gate electrode 616 can comprise any of the materials that comprise the source contact region 120, the drain contact region 124, and the gate electrode 116. The spacer regions 530, 532, and 571 can comprise any of the materials that comprise the spacer regions 130 and 132, respectively.

Any of the perovskite FET fabrication methods described herein, including methods 1000, 1100, and 1200 described below may be performed using any suitable microelectronic fabrication techniques. For example, film deposition—such as depositing layers, filling (backfilling) portions of layers (e.g., filling removed portions of layers or removed layers), and filling via or contact openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning—such as dielectric, ferromagnet, magnetoelectric layer patterning—may be performed using any suitable techniques, such as photolithography-based patterning and etching (e.g., dry etching or wet etching).

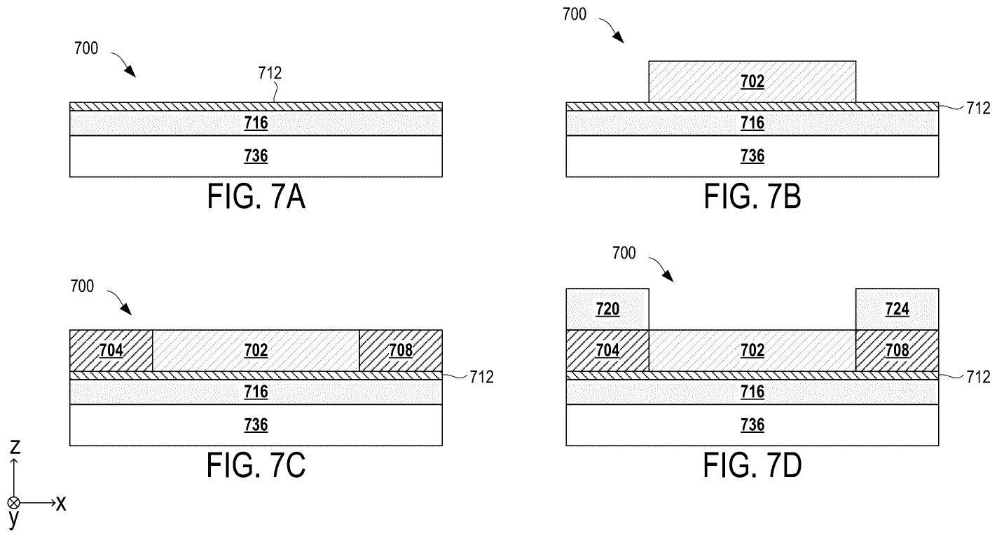

FIGS. 7A-7D illustrate a first example fabrication of a perovskite oxide FET. FIG. 7A illustrates a structure 700 after formation of a gate electrode 716 and a gate dielectric layer 712 on a substrate 736. The gate electrode 716 comprises a first metal. The gate dielectric layer 712 comprises a first perovskite material and is positioned adjacent to the gate electrode 716. The gate electrode 716 is positioned between the gate dielectric layer 712 and the substrate 736. FIG. 7B illustrates the structure 700 after forming a layer positioned adjacent to the gate dielectric layer 712, the layer comprising a second perovskite material and a first dopant, and patterning of the layer to form a channel region 702. FIG. 7C illustrates the structure 700 after formation of a source region 704 and a drain region 708 comprising a third perovskite material and a second dopant. The source region 704 and the drain region 708 are positioned laterally adjacent to the channel region 702. A peak concentration of the second dopant in the source and drain regions 704 and 708 are greater than a peak concentration of the first dopant in the channel region 702. FIG. 7D illustrates the structure 700 after formation of source and drain contact regions 720 and 724 comprising the first metal or a second metal, the source and drain contact regions positioned adjacent to the source and drain regions 704 and 708, respectively. The gate electrode 716 is the back gate of a perovskite oxide FET and can control the follow of current between the source and drain regions 704 and 708.

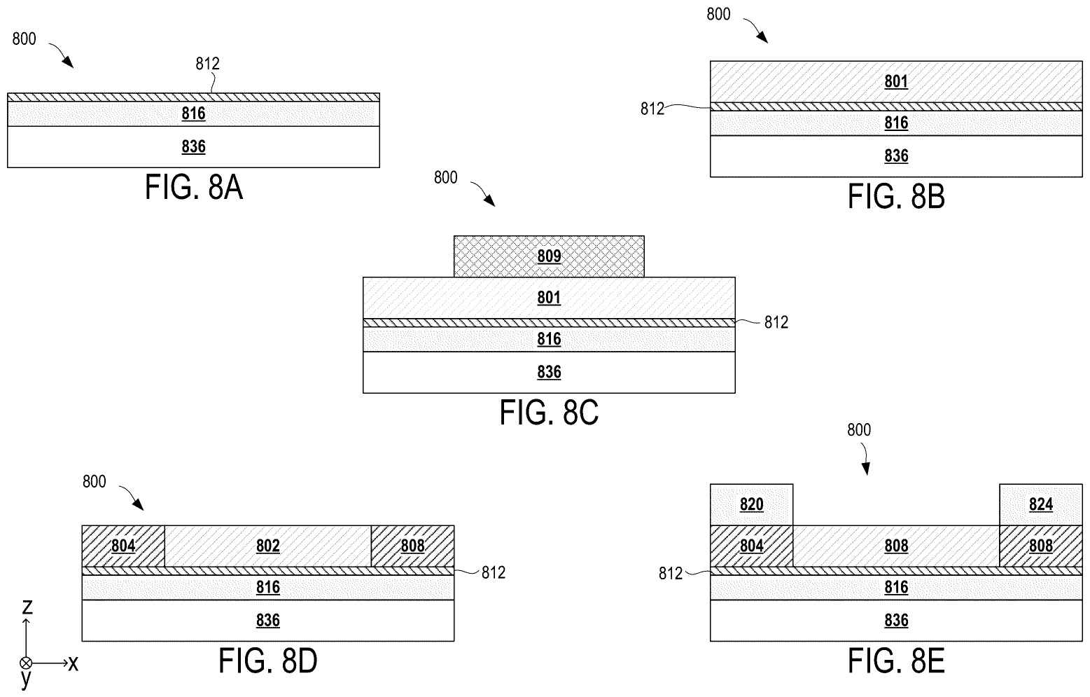

FIGS. 8A-8E illustrate a second example fabrication of a perovskite oxide FET. FIG. 8A illustrates a structure 800 after formation of a gate electrode 816 and a gate dielectric layer 812 on a substrate 836. The gate electrode 816 comprises a first metal. The gate dielectric layer 812 comprises a first perovskite material and is positioned adjacent to the gate electrode 816. The gate electrode 816 is positioned between the gate dielectric layer 812 and the substrate 836. FIG. 8B illustrates the structure 800 after forming a layer 801 positioned adjacent to the gate dielectric layer 812, the layer comprising a second perovskite material and a first dopant. FIG. 8C illustrates the structure 800 after the addition of a second dopant to selected portions of the layer 801, a source region 804 comprising a first portion of the selected portions of the layer 801, a drain region 808 comprising a second portion of the selected portions of the layer 801, the channel region 802 comprising a portion of the layer 801 protected from the addition of the second dopant to the layer 801. The second dopant is selectively added to the layer 801 through formation of a layer 809 over a portion of the layer 801 that protects the layer 801 from addition of the dopants (via ion implantation, diffusion, etc.). A peak concentration of the second dopant in the source and drain regions 804 and 808 are greater than a peak concentration of the first dopant in the channel region 802. FIG. 8D illustrates the structure 800 after formation of source and drain contact regions 820 and 824 comprising the first metal or a second metal, the source and drain contact regions positioned adjacent to the source and drain regions 804 and 808, respectively. The gate electrode 816 is the back gate of a perovskite oxide FET and can control the follow of current between the source and drain regions 804 and 808.

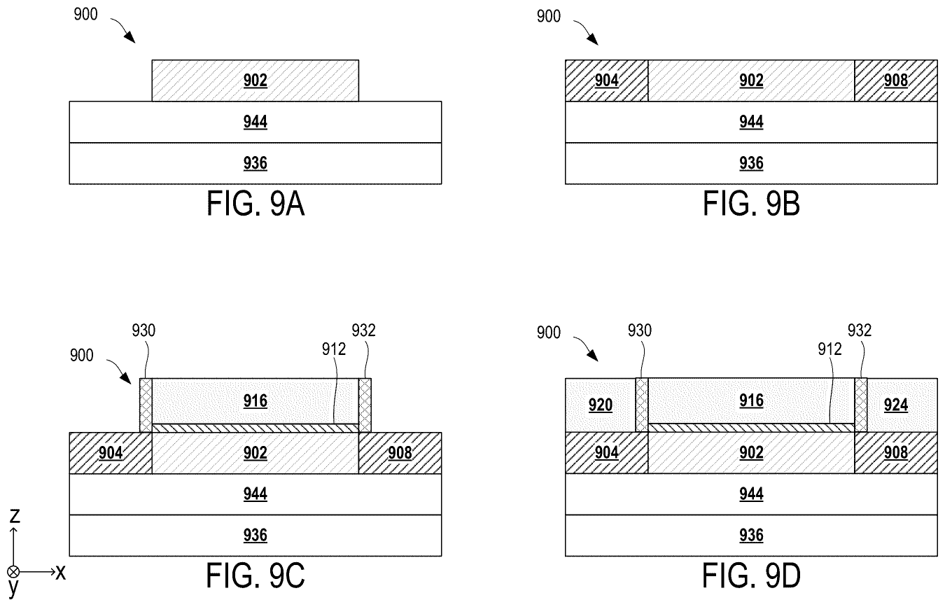

FIGS. 9A-9D illustrate a third example fabrication of a perovskite oxide FET. FIG. 9A illustrates a structure 900 after formation of a buffer layer 944 and a layer on a substrate or template layer 936, and patterning of the layer to form a channel region 902. The channel region 902 comprises a first perovskite material doped with a first dopant. The buffer layer 944 is positioned between the channel region 902 and the substrate or template layer 936. FIG. 9B illustrates the structure 900 after formation of source and drain regions 904 and 908 comprising a second perovskite material, the second perovskite material comprising a second dopant. The channel region 902 is positioned laterally between the source region 904 and the drain region 908, and a peak concentration of the second dopant in the source region 904 is greater than a peak concentration of the first dopant in the channel region. FIG. 9C illustrates the structure 900 after formation of a gate dielectric layer 912 comprising a third perovskite material and located on the channel region 902, formation of a gate electrode 916 comprising a first metal and located on the gate dielectric layer 912, and formation of spacer regions 930 and 932. The gate dielectric layer 912 is positioned between the gate electrode 916 and the channel region 902. FIG. 9D illustrates the structure 900 after formation of source and drain contact regions 920 and 924 comprising the first metal or a second metal, the source and drain contact regions positioned adjacent to the source and drain regions 904 and 908, respectively.

Formation of the layers in the fabrication processing illustrated in FIGS. 7A-7D, 8A-8E, and 9A-9D can be performed, for example, by deposition, and patterning of layers to form the channel, source, and drain regions, as well as the source and drain contact regions can be performed using a photolithography process. Doping in the channel, drain and source regions 802, 804, and 808 can be performed via in-situ doping during a deposition process or by other methods, such as by ion implantation and/or diffusion.

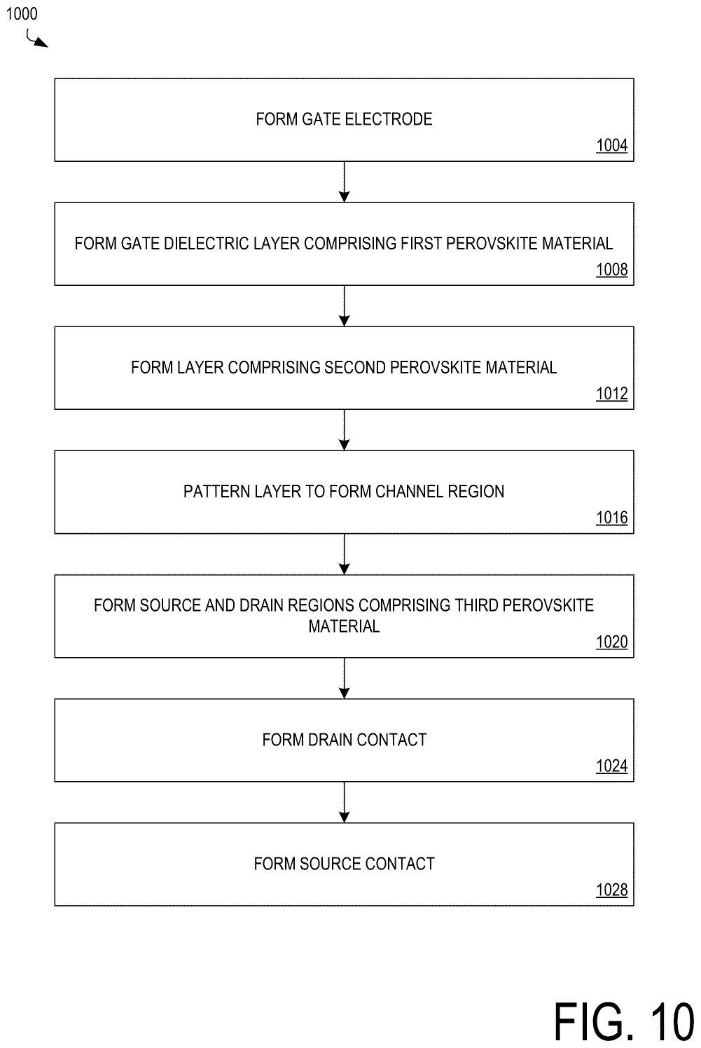

FIG. 10 illustrates a first example perovskite oxide FET fabrication method. The method 1000 can be performed by, for example, an integrated circuit component manufacturer. At 1004, a gate electrode is formed, the gate electrode comprising a first metal and located on a substrate. At 1008, a gate dielectric layer is formed, the gate dielectric layer comprising a first perovskite material, the gate dielectric layer located on the gate electrode. At 1012, a layer comprising a second perovskite material and a first dopant and positioned adjacent to the gate dielectric layer is formed. At 1016, the layer is patterned to form a channel region. At 1020, a source region and a drain region are formed, the source region and the drain region comprising a third perovskite material and a second dopant, the source region and the drain region positioned laterally adjacent to the channel region. At 1024, a drain contact region comprising the first metal or a second metal and positioned adjacent to the drain region is formed. At 1028, a source contact region is formed comprising the first metal or the second metal and positioned adjacent to the source region.

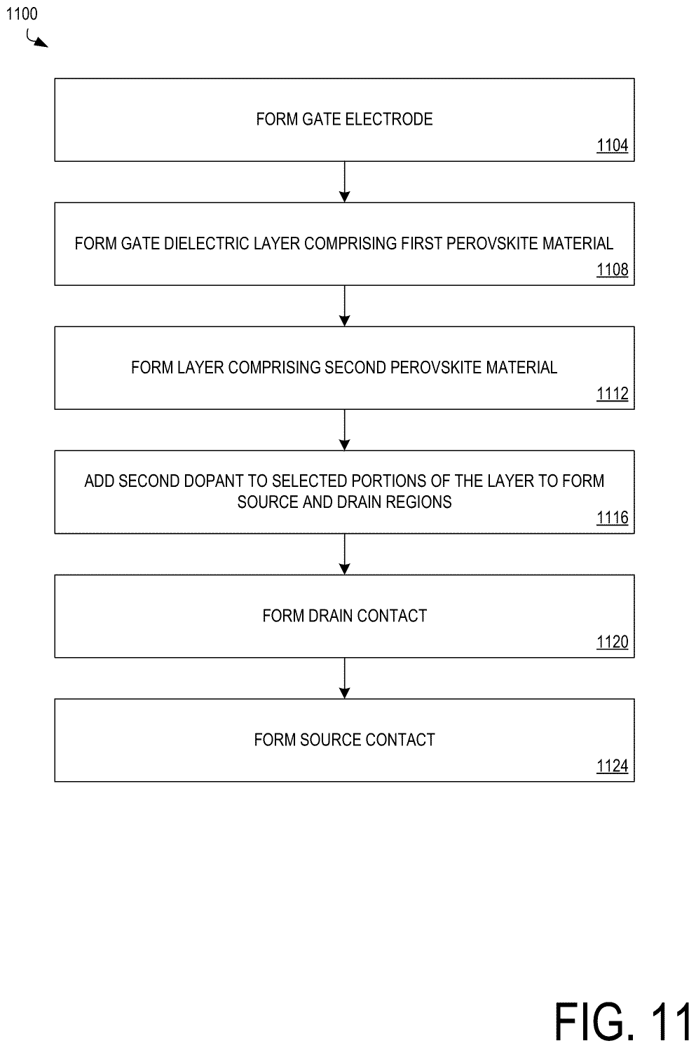

FIG. 11 illustrates a second example perovskite oxide FET fabrication method. The method 1100 can be performed by, for example, an integrated circuit component manufacturer. At 1104, a gate electrode is formed, the gate electrode comprising a first metal and located on a substrate. At 1108, a gate dielectric layer is formed, the gate dielectric layer comprising a first perovskite material, the gate dielectric layer located on the gate electrode. At 1112, a second dopant is added to selected portions of the layer, a source region comprising a first portion of the selected portions of the layer, a drain region comprising a second portion of the selected portions of the layer. At 1116, a source region and a drain region are formed, the source region and the drain region comprising a third perovskite material and a second dopant, the source region and the drain region positioned laterally adjacent to the channel region. At 1120, a drain contact region comprising the first metal or a second metal and positioned adjacent to the drain region is formed. At 1124, a source contact region is formed comprising the first metal or the second metal and positioned adjacent to the source region.

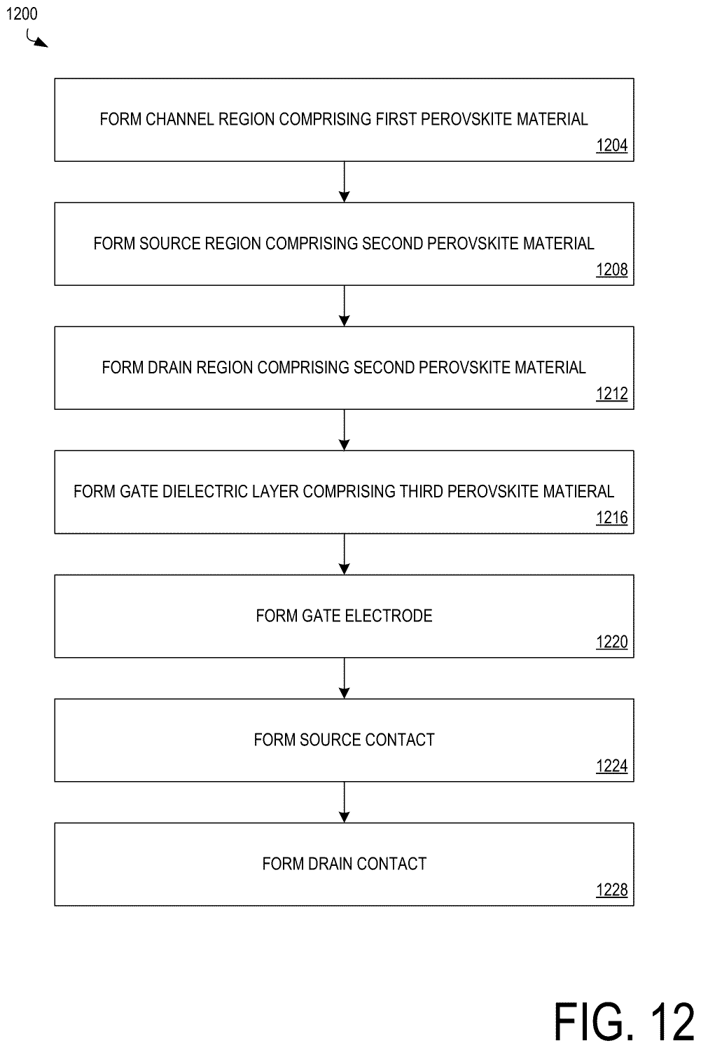

FIG. 12 illustrates a third example perovskite oxide FET fabrication method. The method 1100 can be performed by, for example, an integrated circuit component manufacturer. At 1204, a channel region comprising a first perovskite material comprising a first dopant is formed, the channel region located on a substrate or template layer. At 1208, a source region comprising a second perovskite material comprising a second dopant is formed. At 1212, a drain region comprising the second perovskite material comprising the second dopant is formed, the channel region positioned laterally between the source region and the drain region, a peak concentration of the second dopant in the source region is greater than a peak concentration of the first dopant in the channel region. At 1216, a gate dielectric layer comprising a third perovskite material and located on the channel region is formed. At 1220, a gate electrode comprising a first metal located on the gate dielectric layer is formed, the gate dielectric layer positioned between the gate electrode and the channel region. At 1224, a source contact region comprising the first metal or a second metal and positioned adjacent to the source region is formed. At 1228, a drain contact region comprising the first metal or the second metal and positioned adjacent to the drain region is formed.

The perovskite FETs described herein can be used in any processor unit or integrated circuit component described or referenced herein. An integrated circuit component comprising CFET devices can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

The perovskite FETs disclosed herein can be located on the same integrated circuit die with a silicon-based FET (a FET having source, drain, and channel regions comprising silicon) of any of the field effect transistor types described or referenced herein (e.g., planar, FinFET, GAAFET, stacked GAAFET, forksheet device, CFET device).

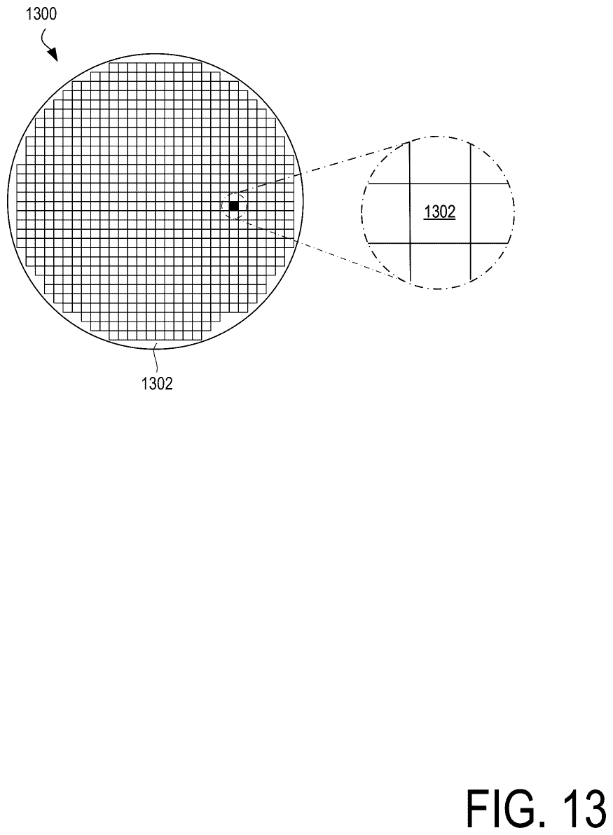

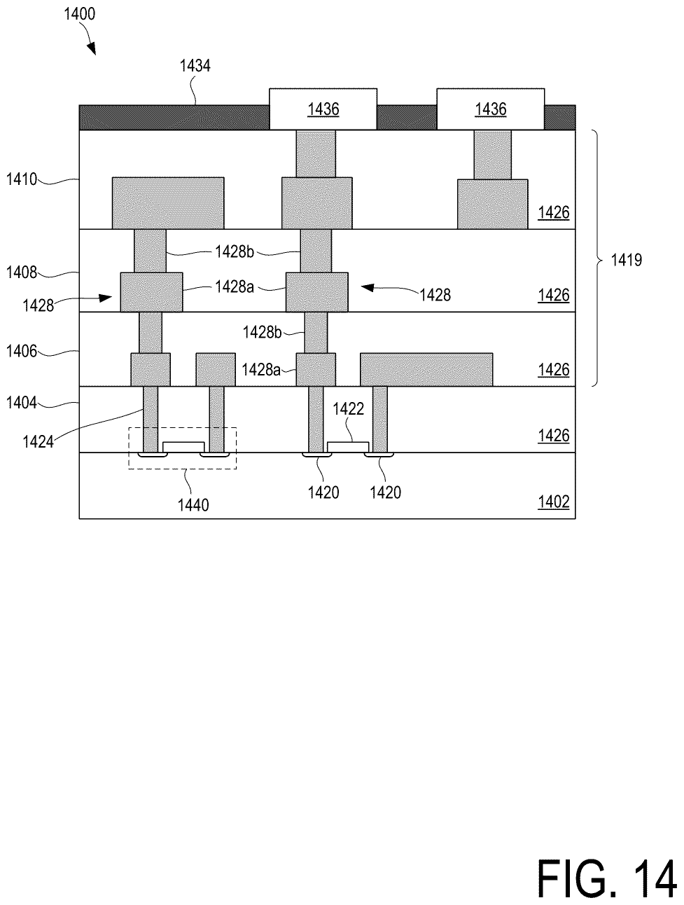

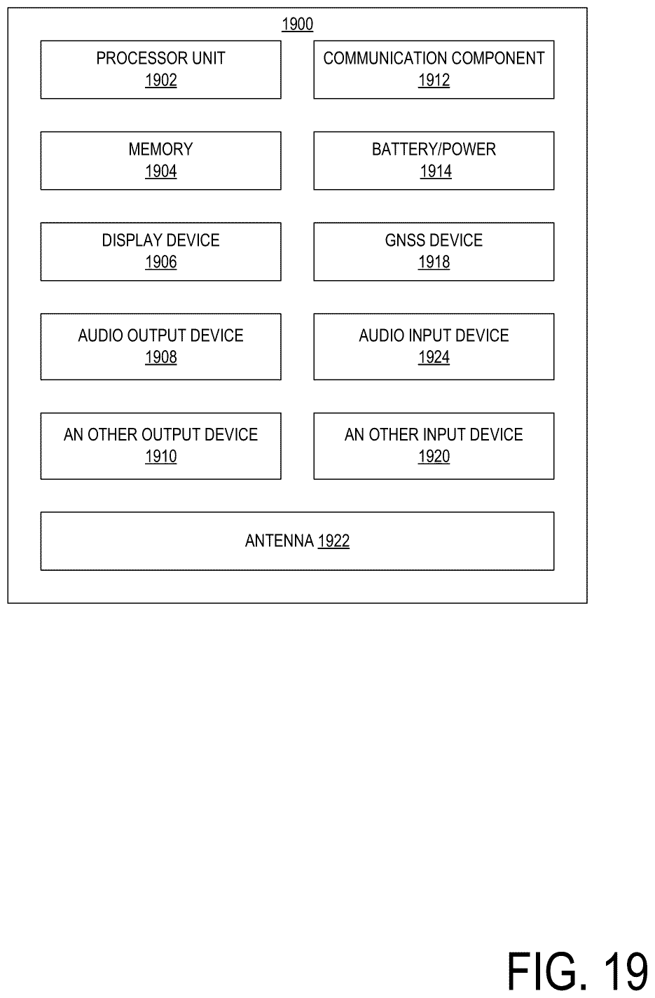

FIG. 13 is a top view of a wafer 1300 and dies 1302 that may be included in any of the microelectronic assemblies disclosed herein. The wafer 1300 may be composed of semiconductor and/or perovskite material(s) and may include one or more dies 1302 having integrated circuit structures, such as perovskite oxide FETs, formed on a surface of the wafer 1300. The individual dies 1302 may be a repeating unit of an integrated circuit product that includes any suitable integrated circuit. After the fabrication of the semiconductor product is complete, the wafer 1300 may undergo a singulation process in which the dies 1302 are separated from one another to provide discrete “chips” of the integrated circuit product. The die 1302 may include one or more transistors (e.g., some of the transistors 1440 of FIG. 14, discussed below, any of the perovskite oxide FETS disclosed herein), supporting circuitry to route electrical signals to the transistors, passive components (e.g., signal traces, resistors, capacitors, or inductors), and/or any other integrated circuit components. In some embodiments, the wafer 1300 or the die 1302 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1302. For example, a memory array formed by multiple memory devices may be formed on a same die 1302 as a processor unit (e.g., the processor unit 1902 of FIG. 19) or other logic that is configured to store information in the memory devices or execute instructions stored in the memory array. Various ones of the microelectronic assemblies disclosed herein may be manufactured using a die-to-wafer assembly technique in which some dies 1302 are attached to a wafer 1300 that include others of the dies 1302, and the wafer 1300 is subsequently singulated.

FIG. 14 is a cross-sectional side view of an integrated circuit device 1400 that may be included in any of the microelectronic assemblies disclosed herein. One or more of the integrated circuit devices 1400 may be included in one or more dies 1302 (FIG. 13). The integrated circuit device 1400 may be formed on a die substrate 1402 (e.g., the wafer 1300 of FIG. 13) and may be included in a die (e.g., the die 1302 of FIG. 13). The die substrate 1402 may be a semiconductor substrate composed of semiconductor material systems including, for example, n-type or p-type materials systems (or a combination of both). The die substrate 1402 may include, for example, a crystalline substrate formed using a bulk silicon or a silicon-on-insulator (SOI) substructure. In some embodiments, the die substrate 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an integrated circuit device 1400 may be used. The die substrate 1402 may be part of a singulated die (e.g., the dies 1302 of FIG. 13) or a wafer (e.g., the wafer 1300 of FIG. 13).

The integrated circuit device 1400 may include one or more device layers 1404 disposed on the die substrate 1402. The device layer 1404 may include features of one or more transistors 1440 (e.g., metal oxide semiconductor field-effect transistors (MOSFETs), the perovskite oxide FETs disclosed herein) formed on the die substrate 1402. The transistors 1440 may include, for example, one or more source and/or drain (S/D) regions 1420, a gate 1422 to control current flow between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors and transistor device may include FinFET transistors, such as double-gate transistors or tri-gate transistors, wrap-around or all-around gate transistors, such as nanoribbon, nanosheet, or nanowire transistors, forksheet transistor devices, and complementary FET (CFET) devices.

FIGS. 15A-15D are simplified perspective views of example planar, FinFET, gate-all-around, and stacked gate-all-around transistors. The transistors illustrated in FIGS. 15A-15D are formed on a substrate 1516 having a surface 1508. Dielectric regions 1514 separate the source and drain regions of the transistors from other transistors and from a bulk region 1518 of the substrate 1516.

FIG. 15A is a perspective view of an example planar transistor 1500 comprising a gate 1502 that controls current flow between a source region 1504 and a drain region 1506. The transistor 1500 is planar in that the source region 1504 and the drain region 1506 are planar with respect to the substrate surface 1508.

FIG. 15B is a perspective view of an example FinFET 1520 comprising a gate 1522 that controls current flow between a source region 1524 and a drain region 1526. The transistor 1520 is non-planar in that the source region 1524 and the drain region 1526 comprise “fins” that extend upwards from the substrate surface 1528. As the gate 1522 encompasses three sides of the semiconductor fin that extends from the source region 1524 to the drain region 1526, the transistor 1520 can be considered a tri-gate transistor. FIG. 15B illustrates one S/D fin extending through the gate 1522, but multiple S/D fins can extend through the gate of a FinFET transistor.

FIG. 15C is a perspective view of a gate-all-around (GAA) transistor (GAAFET) 1540 comprising a gate 1542 that controls current flow between a source region 1544 and a drain region 1546 of a strip 1548 comprising a semiconductor (semiconductor strip). The transistor 1540 is non-planar in that the strip 1548 is elevated from the substrate surface 1508.

FIG. 15D is a perspective view of a GAA transistor 1560 comprising a gate 1562 that controls current flow between source regions 1564 and drain regions 1566 of multiple elevated semiconductor strips 1568. The transistor 1560 is a stacked GAA transistor as the gate controls the flow of current between multiple elevated S/D regions stacked on top of each other. The transistors 1540 and 1560 can be referred to as gate-all-around transistors as the gates encompass all sides of the portions of the semiconductor strips that extend from the source regions to the drain regions. The transistors 1540 and 1560 can alternatively be referred to as nanowire, nanosheet, or nanoribbon transistors and the semiconductor strips that pass through the gate region can be referred to as nanowires, nanowires, or nanoribbons.

FIGS. 16A and 16B are perspective and cross-sectional views of an example forksheet transistor device. Generally, a forksheet transistor device comprises an n-type stacked GAAFET located next to a p-type stacked GAAFET with a dielectric region separating the nanoribbons (nanosheets, nanowires) forming the source, drain, and channel regions of the two GAAFETs. The forksheet transistor device 1660 is formed on a substrate 1616 having a surface 1608. The n-type and p-type GAAFETs comprise three vertically stacked nanoribbons 1690 and 1691, respectively. Each nanoribbon 1690 of the n-type GAAFET is coplanar with a nanoribbon 1691 of the p-type GAAFET. The substrate 1616 comprises an isolation region 1614 located on top of a bulk region 1618. A dielectric region 1698 separates the nanoribbons 1690 of the n-type GAAFET from the nanoribbons 1691 of the p-type GAAFET. A first portion 1670 of the dielectric region 1698 is positioned between n-type source regions 1664 and p-type source regions 1672, a second portion 1682 of the dielectric region 1698 is located between n-type drain regions 1666 (not viewable in FIG. 16A) and p-type drain regions 1674, and a third portion 1680 of the dielectric region 1698 is located between channel regions 1665 of nanoribbons 1690 and channel regions 1673 of nanoribbons 1691. In some embodiments, the dielectric region 1698 can be an extension of the substrate isolation region 1614. The gate 1662 controls current flow between the n-type source 1664 and drain 1666 regions, and the p-type source 1672 and drain 1674 regions.

FIG. 16B is a cross-sectional view of the gate region of the forksheet transistor device 1660 taken along the line A-A′ of FIG. 16A. Channel regions 1665 connect n-type source regions 1664 to n-type drain regions 1666, channel regions 1673 connect p-type source regions 1672 to p-type drain regions 1674, and the third portion 1680 of the dielectric region 1698 separates the channel regions 1665 from the channel regions 1673 and connects the first portion 1670 of the dielectric region 1698 to the second portion 1682 of the dielectric region 1698. Thus, the forksheet transistor device 1660 comprise an n-type transistor comprising n-type source regions 1664, channel region 1665, n-type drain regions 1666, and gate 1662; and a p-type transistor comprising p-type source regions 1672, channel regions 1673, p-type drain regions 1674, and gate 1662. The gate 1662 is shared by the n-type and p-type GAAFETs. The forksheet transistor architecture can provide for reduced spacing between n-type and p-type S/D regions in adjacent GAAFETs relative to that in adjacent independent GAAFETs of the type illustrated in FIG. 15D. The forksheet transistor architecture can thus allow for increased transistor packing density relative to the packing of independent GAAFETs or increased active transistor width at the same transistor packing density as independent GAAFETs.

FIGS. 17A and 17B are perspective and cross-sectional views of an example complementary field-effect-transistor (CFET) device. FIG. 17B is a cross-sectional view of the CFET device 1700 taken through the gate region and taken along the line B-B′ of FIG. 17A. The CFET device 1700 comprises vertically stacked GAAFETs 1742 and 1744. In FIGS. 17A and 17B, transistor 1742 is an n-type transistor, and transistor 1744 is a p-type transistor, but in other embodiments, a CFET device can comprise a p-type transistor located above an n-type transistor. The transistors 1742 and 1744 are formed on a substrate 1716 having a surface 1708. The substrate 1716 comprises an isolation region 1714 located on top of a bulk region 1718.

The n-type and p-type transistors 1742 and 1744 comprise a gate 1782 shared by both transistors that controls current flow between the source and drain regions of nanoribbons 1710 and 1720, respectively. The transistors 1742 and 1744 comprise three nanoribbons but the transistors of a CFET device can have any number of nanoribbons and different transistors of a CFET device can have a different number of nanoribbons. The n-type transistor 1742 comprises n-type source regions 1764 connected to n-type drain regions 1766 by channel regions 1763 and the p-type transistor 1744 comprises p-type source regions 1772 connected to p-type drain regions 1774 by channel regions 1773. The transistor stacking employed by the CFET device architecture can provide for improved transistor density in the x- and y-dimensions or increased transistor width at the same transistor density relative to other gate-all-around transistor architectures, such as those illustrated in FIGS. 15D, 16A, and 16B. In some embodiments, the CFET device 1700 can be formed monolithically, with the upper and lower transistors formed on the same substrate, or sequentially, with the lower transistor (e.g., 1744) formed on a first substrate and the upper transistor (e.g., 1742) formed on a second substrate, the upper transistor integrated with the lower transistor through transfer of the upper transistor from the second substrate to the first substrate.

Returning to FIG. 14, a transistor 1440 may include a gate 1422 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used. A high-k dielectric material used in a perovskite oxide FET can be any of the perovskite oxide materials disclosed herein that have a dielectric constant greater than that of silicon dioxide.

The gate electrode may be formed on the gate dielectric and may include at least one p-type work function metal or n-type work function metal, depending on whether the transistor 1440 is to be a p-type semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning). The gate electrode of a perovskite FET can comprise any other gate electrode material disclosed herein.

In some embodiments, when viewed as a cross-section of the transistor 1440 along the source-channel-drain direction, the gate electrode may consist of a U-shaped structure that includes a bottom portion substantially parallel to the surface of the die substrate 1402 and two sidewall portions that are substantially perpendicular to the top surface of the die substrate 1402. In other embodiments, at least one of the metal layers that form the gate electrode may simply be a planar layer that is substantially parallel to the top surface of the die substrate 1402 and does not include sidewall portions substantially perpendicular to the top surface of the die substrate 1402. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride, as well as an insulating perovskite oxide. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of individual transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes them to diffuse farther into the die substrate 1402 may follow the ion-implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form a metallization stack (also referred to as an “ILD stack”) 1419 of the integrated circuit device 1400.

The interconnect structures 1428 may be arranged within the interconnect layers 1406-1410 to route electrical signals according to a wide variety of designs; in particular, the arrangement is not limited to the particular configuration of interconnect structures 1428 depicted in FIG. 14. Although a particular number of interconnect layers 1406-1410 is depicted in FIG. 14, embodiments of the present disclosure include integrated circuit devices having more or fewer interconnect layers than depicted.

In some embodiments, the interconnect structures 1428 may include lines 1428a and/or vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and out of the page and/or in a direction across the page from the perspective of FIG. 14. The vias 1428b may be arranged to route electrical signals in a direction of a plane that is substantially perpendicular to the surface of the die substrate 1402 upon which the device layer 1404 is formed. In some embodiments, the vias 1428b may electrically couple lines 1428a of different interconnect layers 1406-1410 together.

The interconnect layers 1406-1410 may include a dielectric material 1426 disposed between the interconnect structures 1428, as shown in FIG. 14. In some embodiments, dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same. The device layer 1404 may include a dielectric material 1426 disposed between the transistors 1440 and a bottom layer of the metallization stack as well. The dielectric material 1426 included in the device layer 1404 may have a different composition than the dielectric material 1426 included in the interconnect layers 1406-1410; in other embodiments, the composition of the dielectric material 1426 in the device layer 1404 may be the same as a dielectric material 1426 included in any one of the interconnect layers 1406-1410.

A first interconnect layer 1406 (referred to as Metal 1 or “M1”) may be formed directly on the device layer 1404. In some embodiments, the first interconnect layer 1406 may include lines 1428a and/or vias 1428b, as shown. The lines 1428a of the first interconnect layer 1406 may be coupled with contacts (e.g., the S/D contacts 1424) of the device layer 1404. The vias 1428b of the first interconnect layer 1406 may be coupled with the lines 1428a of a second interconnect layer 1408.

The second interconnect layer 1408 (referred to as Metal 2 or “M2”) may be formed directly on the first interconnect layer 1406. In some embodiments, the second interconnect layer 1408 may include via 1428b to couple the lines 1428 of the second interconnect layer 1408 with the lines 1428a of a third interconnect layer 1410. Although the lines 1428a and the vias 1428b are structurally delineated with a line within individual interconnect layers for the sake of clarity, the lines 1428a and the vias 1428b may be structurally and/or materially contiguous (e.g., simultaneously filled during a dual-damascene process) in some embodiments.

The third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406. In some embodiments, the interconnect layers that are “higher up” in the metallization stack 1419 in the integrated circuit device 1400 (i.e., farther away from the device layer 1404) may be thicker that the interconnect layers that are lower in the metallization stack 1419, with lines 1428a and vias 1428b in the higher interconnect layers being thicker than those in the lower interconnect layers.

The integrated circuit device 1400 may include a solder resist material 1434 (e.g., polyimide or similar material) and one or more conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to external devices. For example, solder bonds may be formed on the one or more conductive contacts 1436 to mechanically and/or electrically couple an integrated circuit die including the integrated circuit device 1400 with another component (e.g., a printed circuit board). The integrated circuit device 1400 may include additional or alternate structures to route the electrical signals from the interconnect layers 1406-1410; for example, the conductive contacts 1436 may include other analogous features (e.g., posts) that route the electrical signals to external components.

In some embodiments in which the integrated circuit device 1400 is a double-sided die, the integrated circuit device 1400 may include another metallization stack (not shown) on the opposite side of the device layer(s) 1404. This metallization stack may include multiple interconnect layers as discussed above with reference to the interconnect layers 1406-1410, to provide conductive pathways (e.g., including conductive lines and vias) between the device layer(s) 1404 and additional conductive contacts (not shown) on the opposite side of the integrated circuit device 1400 from the conductive contacts 1436.

In other embodiments in which the integrated circuit device 1400 is a double-sided die, the integrated circuit device 1400 may include one or more through silicon vias (TSVs) through the die substrate 1402; these TSVs may make contact with the device layer(s) 1404, and may provide conductive pathways between the device layer(s) 1404 and additional conductive contacts (not shown) on the opposite side of the integrated circuit device 1400 from the conductive contacts 1436. In some embodiments, TSVs extending through the substrate can be used for routing power and ground signals from conductive contacts on the opposite side of the integrated circuit device 1400 from the conductive contacts 1436 to the transistors 1440 and any other components integrated into the die 1400, and the metallization stack 1419 can be used to route I/O signals from the conductive contacts 1436 to transistors 1440 and any other components integrated into the die 1400.

Multiple integrated circuit devices 1400 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

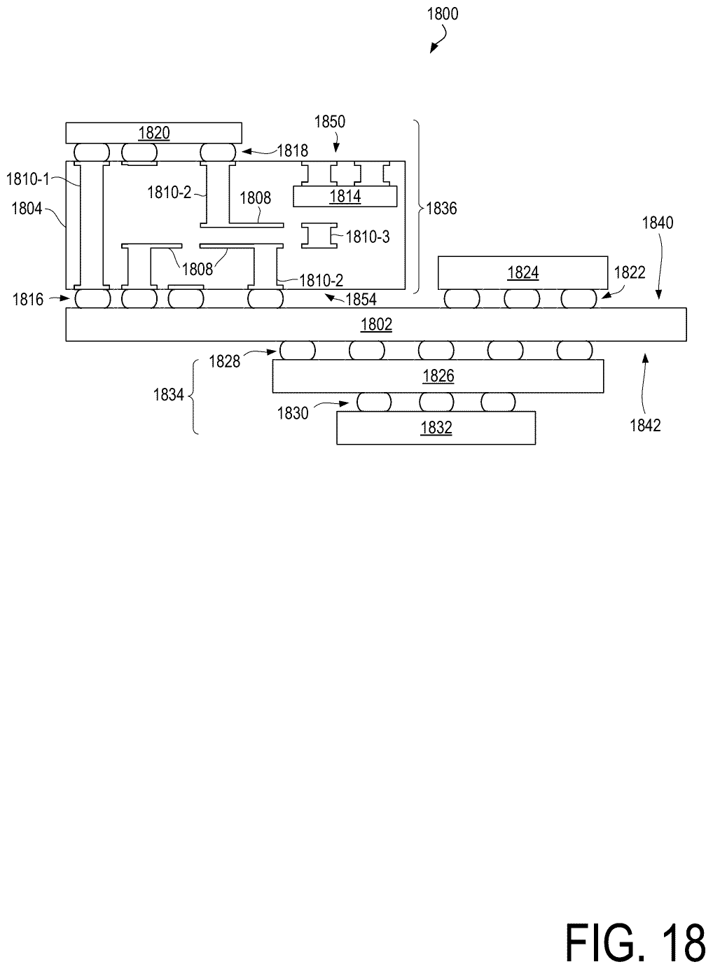

FIG. 18 is a cross-sectional side view of an integrated circuit device assembly 1800 that may include any of the microelectronic assemblies disclosed herein. In some embodiments, the integrated circuit device assembly 1800 may be a microelectronic assembly. The integrated circuit device assembly 1800 includes a number of components disposed on a circuit board 1802 (which may be a motherboard, system board, mainboard, etc.). The integrated circuit device assembly 1800 includes components disposed on a first face 1840 of the circuit board 1802 and an opposing second face 1842 of the circuit board 1802; generally, components may be disposed on one or both faces 1840 and 1842. Any of the integrated circuit components discussed below with reference to the integrated circuit device assembly 1800 may take the form of any suitable ones of the embodiments of the microelectronic assemblies disclosed herein.

In some embodiments, the circuit board 1802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1802. In other embodiments, the circuit board 1802 may be a non-PCB substrate. In some embodiments the circuit board 1802 may be, for example, the circuit board 133. The integrated circuit device assembly 1800 illustrated in FIG. 18 includes a package-on-interposer structure 1836 coupled to the first face 1840 of the circuit board 1802 by coupling components 1816. The coupling components 1816 may electrically and mechanically couple the package-on-interposer structure 1836 to the circuit board 1802, and may include solder balls (as shown in FIG. 18), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1816 may serve as the coupling components illustrated or described for any of the substrate assembly or substrate assembly components described herein, as appropriate.

The package-on-interposer structure 1836 may include an integrated circuit component 1820 coupled to an interposer 1804 by coupling components 1818. The coupling components 1818 may take any suitable form for the application, such as the forms discussed above with reference to the coupling components 1816. Although a single integrated circuit component 1820 is shown in FIG. 18, multiple integrated circuit components may be coupled to the interposer 1804; indeed, additional interposers may be coupled to the interposer 1804. The interposer 1804 may provide an intervening substrate used to bridge the circuit board 1802 and the integrated circuit component 1820.

The integrated circuit component 1820 may be a packaged or unpacked integrated circuit product that includes one or more integrated circuit dies (e.g., the die 1302 of FIG. 13, the integrated circuit device 1400 of FIG. 14) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1820, a single monolithic integrated circuit die comprises solder bumps attached to contacts on the die. The solder bumps allow the die to be directly attached to the interposer 1804. The integrated circuit component 1820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1804 may spread connections to a wider pitch or reroute a connection to a different connection. For example, the interposer 1804 may couple the integrated circuit component 1820 to a set of ball grid array (BGA) conductive contacts of the coupling components 1816 for coupling to the circuit board 1802. In the embodiment illustrated in FIG. 18, the integrated circuit component 1820 and the circuit board 1802 are attached to opposing sides of the interposer 1804; in other embodiments, the integrated circuit component 1820 and the circuit board 1802 may be attached to a same side of the interposer 1804. In some embodiments, three or more components may be interconnected by way of the interposer 1804.

In some embodiments, the interposer 1804 may be formed as a PCB, including multiple metal layers separated from one another by layers of dielectric material and interconnected by electrically conductive vias. In some embodiments, the interposer 1804 may be formed of an epoxy resin, a fiberglass-reinforced epoxy resin, an epoxy resin with inorganic fillers, a ceramic material, or a polymer material such as polyimide. In some embodiments, the interposer 1804 may be formed of alternate rigid or flexible materials that may include the same materials described above for use in a semiconductor substrate, such as silicon, germanium, and other group III-V and group IV materials. The interposer 1804 may include metal interconnects 1808 and vias 1810, including but not limited to through hole vias 1810-1 (that extend from a first face 1850 of the interposer 1804 to a second face 1854 of the interposer 1804), blind vias 1810-2 (that extend from the first or second faces 1850 or 1854 of the interposer 1804 to an internal metal layer), and buried vias 1810-3 (that connect internal metal layers).

In some embodiments, the interposer 1804 can comprise a silicon interposer. Through silicon vias (TSV) extending through the silicon interposer can connect connections on a first face of a silicon interposer to an opposing second face of the silicon interposer. In some embodiments, an interposer 1804 comprising a silicon interposer can further comprise one or more routing layers to route connections on a first face of the interposer 1804 to an opposing second face of the interposer 1804.

The interposer 1804 may further include embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art. In embodiments where the interposer is a non-printed circuit board

The integrated circuit device assembly 1800 may include an integrated circuit component 1824 coupled to the first face 1840 of the circuit board 1802 by coupling components 1822. The coupling components 1822 may take the form of any of the embodiments discussed above with reference to the coupling components 1816, and the integrated circuit component 1824 may take the form of any of the embodiments discussed above with reference to the integrated circuit component 1820.

The integrated circuit device assembly 1800 illustrated in FIG. 18 includes a package-on-package structure 1834 coupled to the second face 1842 of the circuit board 1802 by coupling components 1828. The package-on-package structure 1834 may include an integrated circuit component 1826 and an integrated circuit component 1832 coupled together by coupling components 1830 such that the integrated circuit component 1826 is disposed between the circuit board 1802 and the integrated circuit component 1832. The coupling components 1828 and 1830 may take the form of any of the embodiments of the coupling components 1816 discussed above, and the integrated circuit components 1826 and 1832 may take the form of any of the embodiments of the integrated circuit component 1820 discussed above. The package-on-package structure 1834 may be configured in accordance with any of the package-on-package structures known in the art.

FIG. 19 is a block diagram of an example electrical device 1900 that may include one or more of the microelectronic assemblies or any of the perovskite oxide FETs disclosed herein. For example, any suitable ones of the components of the electrical device 1900 may include one or more of the integrated circuit device assemblies 1800, integrated circuit components 1820, integrated circuit devices 1400, or integrated circuit dies 1302 disclosed herein, and may be arranged in any of the microelectronic assemblies disclosed herein. A number of components are illustrated in FIG. 19 as included in the electrical device 1900, but any one or more of these components may be omitted or duplicated, as suitable for the application. In some embodiments, some or all of the components included in the electrical device 1900 may be attached to one or more motherboards mainboards, or system boards. In some embodiments, one or more of these components are fabricated onto a single system-on-a-chip (SoC) die.

Additionally, in various embodiments, the electrical device 1900 may not include one or more of the components illustrated in FIG. 19, but the electrical device 1900 may include interface circuitry for coupling to the one or more components. For example, the electrical device 1900 may not include a display device 1906, but may include display device interface circuitry (e.g., a connector and driver circuitry) to which a display device 1906 may be coupled. In another set of examples, the electrical device 1900 may not include an audio input device 1924 or an audio output device 1908, but may include audio input or output device interface circuitry (e.g., connectors and supporting circuitry) to which an audio input device 1924 or audio output device 1908 may be coupled.

The electrical device 1900 may include one or more processor units 1902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1900 may include a memory 1904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1904 may include memory that is located on the same integrated circuit die as the processor unit 1902. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1900 can comprise one or more processor units 1902 that are heterogeneous or asymmetric to another processor unit 1902 in the electrical device 1900. There can be a variety of differences between the processing units 1902 in a system in terms of a spectrum of metrics of merit including architectural, microarchitectural, thermal, power consumption characteristics, and the like. These differences can effectively manifest themselves as asymmetry and heterogeneity among the processor units 1902 in the electrical device 1900.

In some embodiments, the electrical device 1900 may include a communication component 1912 (e.g., one or more communication components). For example, the communication component 1912 can manage wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1912 may operate in accordance with other wireless protocols in other embodiments. The electrical device 1900 may include an antenna 1922 to facilitate wireless communications and/or to receive other wireless communications (such as AM or FM radio transmissions).

In some embodiments, the communication component 1912 may manage wired communications, such as electrical, optical, or any other suitable communication protocols (e.g., IEEE 802.3 Ethernet standards). As noted above, the communication component 1912 may include multiple communication components. For instance, a first communication component 1912 may be dedicated to shorter-range wireless communications such as Wi-Fi or Bluetooth, and a second communication component 1912 may be dedicated to longer-range wireless communications such as global positioning system (GPS), EDGE, GPRS, CDMA, WiMAX, LTE, EV-DO, or others. In some embodiments, a first communication component 1912 may be dedicated to wireless communications, and a second communication component 1912 may be dedicated to wired communications.

The electrical device 1900 may include battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include a display device 1906 (or corresponding interface circuitry, as discussed above). The display device 1906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1900 may include an audio output device 1908 (or corresponding interface circuitry, as discussed above). The audio output device 1908 may include any embedded or wired or wirelessly connected external device that generates an audible indicator, such speakers, headsets, or earbuds.

The electrical device 1900 may include an audio input device 1924 (or corresponding interface circuitry, as discussed above). The audio input device 1924 may include any embedded or wired or wirelessly connected device that generates a signal representative of a sound, such as microphones, microphone arrays, or digital instruments (e.g., instruments having a musical instrument digital interface (MIDI) output). The electrical device 1900 may include a Global Navigation Satellite System (GNSS) device 1918 (or corresponding interface circuitry, as discussed above), such as a Global Positioning System (GPS) device. The GNSS device 1918 may be in communication with a satellite-based system and may determine a geolocation of the electrical device 1900 based on information received from one or more GNSS satellites, as known in the art.

The electrical device 1900 may include another output device 1910 (or corresponding interface circuitry, as discussed above). Examples of the other output device 1910 may include an audio codec, a video codec, a printer, a wired or wireless transmitter for providing information to other devices, or an additional storage device.

The electrical device 1900 may include another input device 1920 (or corresponding interface circuitry, as discussed above). Examples of the other input device 1920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1900 may be any other electronic device that processes data. In some embodiments, the electrical device 1900 may comprise multiple discrete physical components. Given the range of devices that the electrical device 1900 can be manifested as in various embodiments, in some embodiments, the electrical device 1900 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods

The following examples pertain to additional embodiments of technologies disclosed herein.

Example 1 includes an apparatus, comprising a substrate or template layer; a channel region comprising a first perovskite material comprising a first dopant; a source region comprising a second perovskite material comprising a second dopant; a drain region comprising the second perovskite material comprising the second dopant, wherein the channel region is positioned laterally between the source region and the drain region, and wherein the source region, the drain region, and the channel region are located on the substrate or template layer, and wherein a peak concentration of the second dopant in the source region is greater than a peak concentration of the first dopant in the channel region; a source contact region comprising a first metal and positioned adjacent to the source region; a drain contact region comprising the first metal and positioned adjacent to the drain region; a gate dielectric layer comprising a third perovskite material and located on the channel region; and a gate electrode comprising the first metal or a second metal located on the gate dielectric layer, the gate dielectric layer positioned between the gate electrode and the channel region.

Example 2 includes the subject matter of Example 1, and further including a fin extending upwards from a surface of the substrate, wherein the fin comprises the source region, the drain region, and the channel region, wherein the gate dielectric layer encompasses an end of the fin.

Example 3 includes the subject matter of Example 1 or 2, wherein the first perovskite material comprises barium, tin, and oxygen; strontium, tin, and oxygen; strontium, titanium, and oxygen; or barium, strontium, tin, and oxygen.

Example 4 includes the subject matter of any one of Examples 1-3, wherein the first dopant comprises lanthanum, neodymium, cesium, cerium, yttrium, vanadium, potassium, or cobalt.

Example 5 includes the subject matter of any one of Examples 1-4, wherein a doping concentration of the first dopant in the channel region is about 3% or less.

Example 6 includes the subject matter of any one of Examples 1-5, wherein a doping concentration of the first dopant in the channel region is in the range of about 0.1% to 3%.

Example 7 includes the subject matter of any one of Examples 1-5, wherein a doping concentration of the second dopant in the source region and the drain region is in the range of about 3% to 15%.

Example 8 includes the subject matter of any one of Examples 1-7, wherein the second perovskite material comprises barium, tin, and oxygen; strontium, tin, and oxygen; strontium, titanium, and oxygen; or barium, strontium, tin, and oxygen.

Example 9 includes the subject matter of any one of Examples 1-8, wherein the second dopant comprises lanthanum, neodymium, cesium, cerium, yttrium, vanadium, potassium, or cobalt.

Example 10 includes the subject matter of any one of Examples 1-9, wherein the first dopant is the same as the second dopant.

Example 11 includes the subject matter of any one of Examples 1-9, wherein the first dopant is different from the second dopant.

Example 12 includes the subject matter of any one of Examples 1-9, wherein the first dopant and the second dopants are n-type dopants.

Example 13 includes the subject matter of any one of Examples 1-9, wherein the first dopant and the second dopants are p-type dopants.

Example 14 includes the subject matter of any one of Examples 1-13, wherein the gate dielectric layer comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 15 includes the subject matter of any one of Examples 1-13, wherein the gate dielectric layer comprises scandium, oxygen, and one of dysprosium, terbium, gadolinium, europium, samarium, neodymium, praseodymium, cerium, and lanthanum.

Example 16 includes the subject matter of any one of Examples 1-13, wherein the gate dielectric layer comprises barium, titanium, and oxygen; barium, zirconium, titanium, and oxygen; barium, calcium, titanium, and oxygen; barium, strontium, titanium, and oxygen; barium, calcium, titanium, zirconium, and oxygen; barium, hafnium, titanium, and oxygen; bismuth, and iron, oxygen; bismuth, lanthanum, iron, and oxygen; bismuth, iron, cobalt, and oxygen; lithium niobium, and oxygen; potassium niobium, and oxygen; gadolinium iron, and oxygen; gadolinium, lanthanum, iron, and oxygen; or hafnium zirconium, and oxygen.

Example 17 includes the subject matter of any one of Examples 1-13, wherein the gate dielectric layer comprises hafnium, oxygen, and one of lanthanum, strontium, aluminum, silicon, yttrium, gadolinium, and zirconium.

Example 18 includes the subject matter of any one of Examples 1-17, further comprising a layer positioned between the substrate and the channel region, the substrate and the source region, and the substrate and the drain region, the layer comprising a fourth perovskite material.

Example 19 includes the subject matter of Example 18, and wherein the fourth perovskite material comprises strontium, titanium, and oxygen and the substrate comprises silicon.

Example 20 includes the subject matter of Example 18, and wherein the fourth perovskite material having a dielectric constant greater than silicon dioxide.

Example 21 includes the subject matter of Example 18, and wherein the fourth perovskite material comprises strontium, ruthenium, and oxygen; strontium, barium, ruthenium, and oxygen; strontium, indium, and oxygen; lanthanum, barium, strontium, and oxygen; lanthanum, strontium, manganese, and oxygen; lanthanum, barium, cobalt, and oxygen; lanthanum, niobium, and oxygen; lanthanum, nickel, and oxygen; lanthanum, ruthenium, and oxygen; strontium, vanadium, and oxygen; strontium, cobalt, and oxygen; strontium, molybdenum, and oxygen; or yttrium, barium, copper, and oxygen.

Example 22 includes the subject matter of any one of Examples 1-13, wherein the gate dielectric layer is a first gate dielectric layer positioned above the channel region and the gate electrode is a first gate electrode, the apparatus further comprising a second gate electrode located below the channel region and comprising the first metal or the second metal; and a second gate dielectric layer positioned below the channel region and between the second gate electrode and the channel region.

Example 23 includes the subject matter of Example 22, and wherein the second gate dielectric comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 24 includes the subject matter of Example 22, and wherein the second gate dielectric comprises scandium, oxygen, and one of dysprosium, terbium, gadolinium, europium, samarium, neodymium, praseodymium, cerium, and lanthanum.

Example 25 includes the subject matter of any one of Examples 1-24, wherein the first metal comprises tungsten, cobalt, titanium, gold, aluminum, molybdenum, chromium, or nickel.

Example 26 includes the subject matter of any one of Examples 1-24, wherein the second metal comprises tungsten, cobalt, titanium, gold, aluminum, molybdenum, chromium, or nickel.

Example 27 includes the subject matter of any one of Examples 1-26, wherein the apparatus further comprises a first spacer region positioned between the gate dielectric layer and the source contact region, a portion of the source region extending under the first spacer region; and a second spacer region positioned between the gate dielectric layer and the drain contact region, a portion of the drain region extending under the second spacer region.

Example 28 includes the subject matter Example 27, and wherein the first spacer region and the second spacer region comprise silicon and oxygen; silicon, oxygen, and one of carbon, fluorine, and hydrogen; or silicon and nitrogen.

Example 29 includes the subject matter of any one of Examples 1-28, wherein the substrate or template layer comprises silicon; silicon and oxygen; or strontium, titanium, and oxygen.

Example 30 includes an apparatus, comprising a substrate or template layer; a channel region comprising a first perovskite material comprising a first dopant; a source region comprising a second perovskite material comprising a second dopant; a drain region comprising the second perovskite material comprising the second dopant, wherein the channel region is positioned laterally between the source region and the drain region, and wherein the source region, the drain region, and the channel region are located on the substrate or template layer, and wherein a peak concentration of the second dopant in the source region is greater than a peak concentration of the first dopant in the channel region; a source contact region comprising a first metal and positioned adjacent to the source region; a drain contact region comprising the first metal and positioned adjacent to on the drain region; a gate dielectric layer comprising a third perovskite material, the gate dielectric layer positioned adjacent to and below the channel region; and a gate electrode located below the gate dielectric layer, the gate electrode comprising the first metal or a second metal, the gate electrode positioned between the substrate or the template layer and the gate dielectric layer, the gate dielectric layer positioned between the gate electrode and the channel region.

Example 31 includes the subject matter of Example 30, and wherein the first perovskite material comprises barium, tin, and oxygen; strontium, tin, and oxygen; strontium, titanium, and oxygen; or barium, strontium, tin, and oxygen.

Example 32 includes the subject matter of any of Examples 30 and 31, and wherein the first dopant comprises lanthanum, neodymium, cesium, cerium, yttrium, vanadium, potassium, or cobalt.

Example 33 includes the subject matter of any one of Examples 30-32, wherein a doping concentration of the first dopant in the channel region is about 3% or less.

Example 34 includes the subject matter of any one of Examples 30-33, wherein a doping concentration of the first dopant in the channel region is in the range of about 0.1% to 3%.

Example 35 includes the subject matter of any one of Examples 30-33, wherein a doping concentration of the second dopant in the source region is in the range of about 3% to 15%.

Example 36 includes the subject matter of any one of Examples 30-35, wherein the second perovskite material comprises barium, tin, and oxygen; strontium, tin, and oxygen; strontium, titanium, and oxygen; or barium, strontium, tin, and oxygen.

Example 37 includes the subject matter of any one of Example 30-36, wherein the second dopant comprises lanthanum, neodymium, cesium, cerium, yttrium, vanadium, potassium, or cobalt.

Example 38 includes the subject matter of any one of Examples 30-37, wherein the first dopant is the same as the second dopant.

Example 39 includes the subject matter of any one of Examples 30-37, wherein the first dopant is different from the second dopant.

Example 40 includes the subject matter of any one of Examples 30-37, wherein the first dopant and the second dopants are n-type dopants.

Example 41 includes the subject matter of any one of Examples 30-37, wherein the first dopant and the second dopants are p-type dopants.

Example 42 includes the subject matter of any one of Examples 30-41, wherein the gate dielectric layer comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 43 includes the subject matter of any one of Examples 30-41, wherein gate dielectric layer further comprises scandium and one of dysprosium, terbium, gadolinium, europium, samarium, neodymium, praseodymium, cerium, and lanthanum.

Example 44 includes the subject matter of any one of Examples 30-43, wherein the first metal comprises tungsten, cobalt, titanium, gold, aluminum, molybdenum, chromium, or nickel.

Example 45 includes the subject matter of any one of Examples 30-43, wherein the second metal comprises tungsten, cobalt, titanium, gold, aluminum, molybdenum, chromium, or nickel.

Example 46 includes the subject matter of any of Examples 30-45, and wherein the substrate or template layer comprises silicon; silicon and oxygen; or strontium, titanium, and oxygen.

Example 47 includes an apparatus, comprising a substrate; one or more layers stacked vertically above and separate from the substrate, individual of the layers comprising a channel region comprising a first perovskite material comprising a first dopant; a first source region comprising a second perovskite material comprising a second dopant; and a first drain region comprising the second perovskite material comprising the second dopant, wherein the channel region is positioned laterally between the source region and the drain region, and wherein a peak concentration of the second dopant in the source is greater than a peak concentration of the first dopant in the channel region; a second source region encompassing a portion of individual of the first source regions, the second source region comprising the second dopant; a second drain region encompassing a portion of individual of the first drain regions, the second drain region comprising the second dopant; a source contact region comprising a first metal and positioned adjacent to the second source region, a drain contact region comprising the first metal and positioned adjacent to the second drain region, and a plurality of gate regions stacked vertically with respect to the substrate, wherein individual of the gate regions comprise a gate dielectric layer comprising a third perovskite material and a gate electrode comprising the first metal or a second metal, wherein for the gate region positioned furthest from the substrate, the gate dielectric layer is positioned between the gate electrode and the channel region of the first layer positioned further from the substrate, and wherein for the other of the gate regions, the gate dielectric layer encircles the gate electrode; wherein individual of the first channel regions are positioned vertically adjacent to two gate regions.

Example 48 includes the subject matter of Example 47, and wherein the first perovskite material comprises barium, tin, and oxygen; strontium, tin, and oxygen; strontium, titanium, and oxygen; or barium, strontium, tin, and oxygen.

Example 49 includes the subject matter of Example 47 or 48, wherein the first dopant comprises lanthanum, neodymium, cesium, cerium, yttrium, vanadium, potassium, or cobalt.

Example 50 includes the subject matter of any one of Examples 47-49, wherein a doping concentration of the first dopant in one of the channel regions is about 3% or less.

Example 51 includes the subject matter of any one of Examples 47-49, wherein a doping concentration of the first dopant in one of the channel regions is in the range of about 0.1% to 3%.

Example 52 includes the subject matter of any one of Examples 47-49, wherein a doping concentration of the second dopant in one of the first source regions is in the range of about 3% to 15%.

Example 53 includes the subject matter of any one of Examples 47-52, wherein the second perovskite material comprises barium, tin, and oxygen; strontium, tin, and oxygen; strontium, titanium, and oxygen; or barium, strontium, tin, and oxygen.

Example 54 includes the subject matter of any one of Examples 47-53, wherein the second dopant comprises lanthanum, neodymium, cesium, cerium, yttrium, vanadium, potassium, or cobalt.

Example 55 includes the subject matter of any one of Examples 47-54, wherein the first dopant is the same as the second dopant.

Example 56 includes the subject matter of any one of Examples 47-54, wherein the first dopant is different from the second dopant.

Example 57 includes the subject matter of any one of Examples 47-54, wherein the first dopant and the second dopants are n-type dopants.

Example 58 includes the subject matter of any one of Examples 47-54, wherein the first dopant and the second dopants are p-type dopants.

Example 59 includes the subject matter of any one of Examples 47-58, wherein individual of the gate dielectric layers comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 60 includes the subject matter of any one of Examples 47-58, wherein individual of the gate dielectric layers comprises scandium, oxygen, and one of dysprosium, terbium, gadolinium, europium, samarium, neodymium, praseodymium, cerium, and lanthanum.

Example 61 includes the subject matter of any one of Examples 47-60, wherein the first metal comprises tungsten, cobalt, titanium, gold, aluminum, molybdenum, chromium, or nickel.

Example 62 includes the subject matter of any one of Examples 47-60, wherein the second metal comprises tungsten, cobalt, titanium, gold, aluminum, molybdenum, chromium, or nickel.

Example 63 includes the subject matter of any one of Examples 47-62, wherein the apparatus further comprises a first spacer region positioned between one of the gate regions and the second source contact region, a portion of one of the first source regions extending under the first spacer region; and a second spacer region positioned between one of the gate regions and the second drain contact region, a portion of one of the first drain regions extending under the second spacer region.

Example 64 includes the subject matter of Example 63, and wherein the first spacer region and the second spacer region comprise silicon and oxygen; silicon, oxygen, and one of carbon, fluorine, and hydrogen; or silicon and nitrogen.

Example 65 includes the subject matter of any one of Examples 57-64, wherein the layers are first layers, the source contact region is a first source contact region, the drain contact region is a first drain contact region, the gate regions are first gate regions, the apparatus further comprising one or more second layers stacked vertically above and separate from the substrate, individual of the second layers comprising a channel region comprising a fourth perovskite material comprising a third dopant; a first source region comprising a fifth perovskite material comprising a fourth dopant; and a first drain region comprising the fifth perovskite material comprising the fourth dopant, wherein the channel region is positioned laterally between the source region and the drain region, and wherein a peak concentration of the fourth dopant in the source region is greater than a peak concentration of the second dopant in the channel region; a third source region encompassing a portion of individual of the first source regions of the second layers, the third source region comprising the fourth dopant; a third drain region encompassing a portion of individual of the first drain regions of the second layers, the third drain region comprising the fourth dopant; a second source contact region comprising the first metal and positioned adjacent to the third source region; a second drain contact region comprising the first metal and positioned adjacent to the third drain region; a middle dielectric layer positioned between the first layers and the second layers; and a plurality of second gate regions stacked vertically with respect to the substrate, wherein individual of the second gate regions comprise a gate dielectric layer comprising a sixth perovskite material and a gate electrode comprising the first metal, the second metal, or a third metal, wherein for the second gate region positioned furthest from the substrate, the gate dielectric layer is positioned between the gate electrode and the channel region of the second layer positioned further from the substrate, and wherein for the other of the second gate regions, the gate dielectric layer encircles the gate electrode; wherein individual of the channel regions of the second layers are positioned vertically adjacent to two second gate regions; and a middle dielectric layer between the first layers and the second layers.

Example 66 includes the subject matter Example 65, and wherein the third and fourth dopants are the same.

Example 67 includes the subject matter of Example 64 or 65, wherein the fourth perovskite material comprises barium, tin, and oxygen; strontium, tin, and oxygen; strontium, titanium, and oxygen; or barium, strontium, tin, and oxygen.

Example 68 includes the subject matter of any one of Examples 65-67, wherein the third dopant comprises lanthanum, neodymium, cesium, cerium, yttrium, vanadium, potassium, or cobalt.

Example 69 includes the subject matter of any one of Examples 65-68, wherein a doping concentration of the third dopant in one of the channel regions of the second layers is about 3% or less.

Example 70 includes the subject matter of any one of Examples 65-68, wherein a doping concentration of the third dopant in one of the channel regions of the second layers is in the range of about 0.1% to 3%.

Example 71 includes the subject matter of any one of Examples 65-68, wherein a doping concentration of the second dopant in one of the source region of the second layers is in the range of about 3% to 15%.

Example 72 includes the subject matter of any one of Examples 65-71, wherein the fifth perovskite material comprises barium, tin, and oxygen; strontium, tin, and oxygen; strontium, titanium, and oxygen; or barium, strontium, tin, and oxygen.

Example 73 includes the subject matter of any one of Examples 65-72, wherein the fourth dopant comprises lanthanum, neodymium, cesium, cerium, yttrium, vanadium, potassium, or cobalt.

Example 74 includes the subject matter of any one of Examples 65-73, wherein the third dopant is the same as the fourth dopant.

Example 75 includes the subject matter of any one of Examples 65-73, wherein the third dopant is different from the second dopant.

Example 76 includes the subject matter of any one of Examples 65-73, wherein the third dopant and the fourth dopant are n-type dopants.

Example 77 includes the subject matter of any one of Examples 65-73, wherein the third dopant and the fourth dopant are p-type dopants.

Example 78 includes the subject matter of any one of Examples 65-77, wherein the gate dielectric layer of the second gate regions comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 79 includes the subject matter of any one of Examples 65-77, wherein individual of the gate dielectric layers comprises scandium, oxygen, and one of dysprosium, terbium, gadolinium, europium, samarium, neodymium, praseodymium, cerium, and lanthanum.

Example 80 includes the subject matter of any one of Examples 65-80, wherein the apparatus further comprises a third spacer region positioned between one of the second gate regions and the third source contact region, a portion of a first source region of one of the second layers extending under the third spacer region; and a fourth spacer region positioned between one of the second gate regions and the third drain contact region, a portion of a first drain regions of one of the second layers extending under the fourth spacer region.

Example 81 includes the subject matter of Example 80, and wherein the first spacer region and the second spacer region comprise silicon and oxygen; silicon, oxygen, and one of carbon, fluorine, and hydrogen; or silicon and nitrogen.

Example 82 includes the subject matter of any one of Examples 47-81, wherein the substrate comprises silicon.

Example 83 includes the subject matter of any one of Examples 1-82, wherein the apparatus is a wafer.

Example 84 includes the subject matter of any one of Examples 1-82, wherein the apparatus is an integrated circuit component.

Example 85 includes the subject matter of any one of Examples 1-82, further comprising a printed circuit board, the integrated circuit component attached to the printed circuit board.

Example 86 includes the subject matter of Example 85, and wherein a memory is attached to the printed circuit board.

Example 87 includes the subject matter of Example 85, and further including a housing of a computing device enclosing the printed circuit board.

Example 88 includes a method of forming a perovskite field effect transistor, the method comprising forming a gate electrode, the gate electrode comprising a first metal and located on a substrate; forming a gate dielectric layer, the gate dielectric layer comprising a first perovskite material, the gate dielectric layer positioned adjacent to the gate electrode, the gate electrode positioned between the gate dielectric layer and the substrate; forming a layer comprising a second perovskite material and a first dopant and positioned adjacent to the gate dielectric layer; patterning the layer to form a channel region; forming a source region and a drain region, the source region and the drain region comprising a third perovskite material and a second dopant, the source region and the drain region positioned laterally adjacent to the channel region; forming a drain contact region comprising the first metal or a second metal and positioned adjacent to the drain region; and forming a source contact region comprising the first metal or the second metal and positioned adjacent to the source region.

Example 89 includes a method of forming a perovskite field effect transistor, the method comprising forming a gate electrode, the gate electrode comprising a first metal and located on a substrate; forming a gate dielectric layer, the gate dielectric layer comprising a first perovskite material, the gate dielectric layer located on the gate electrode; forming a layer comprising a second perovskite material dopant positioned adjacent to the gate dielectric layer; adding a second dopant to selected portions of the layer, a source region comprising a first portion of the selected portions of the layer, a drain region comprising a second portion of the selected portions of the layer; forming a drain contact region comprising the first metal or a second metal and positioned adjacent to the drain region; and forming a source contact region comprising the first metal or the second metal and positioned adjacent to the source region.

Example 90 includes the subject matter of Example 88 or 89, wherein the first perovskite material comprises barium, tin, and oxygen; strontium, tin, and oxygen; strontium, titanium, and oxygen; or barium, strontium, tin, and oxygen.

Example 91 includes the subject matter of any one of Examples 88-90, wherein the first dopant comprises lanthanum, neodymium, cesium, cerium, yttrium, vanadium, potassium, or cobalt.

Example 92 includes the subject matter of any one of Examples 88-91, wherein a doping concentration of the first dopant in the channel region is about 3% or less.

Example 93 includes the subject matter of any one of Examples 88-91, wherein a doping concentration of the first dopant in the channel region is in the range of about 0.1% to 3%.

Example 94 includes the subject matter of any one of Examples 88-91, wherein a doping concentration of the second dopant in the source region is in the range of about 3% to 15%.

Example 95 includes the subject matter of any one of Examples 88-94, wherein the second perovskite material comprises barium, tin, and oxygen; strontium, tin, and oxygen; strontium, titanium, and oxygen; or barium, strontium, tin, and oxygen.

Example 96 includes the subject matter of any one of Examples 88-95, wherein the second dopant comprises lanthanum, neodymium, cesium, cerium, yttrium, vanadium, potassium, or cobalt.

Example 97 includes the subject matter of any one of Examples 88-96, wherein the first dopant is the same as the second dopant.

Example 98 includes the subject matter of any one of Examples 88-96, wherein the first dopant is different from the second dopant.

Example 99 includes the subject matter of any one of Examples 88-96, wherein the first dopant and the second dopants are n-type dopants.

Example 100 includes the subject matter of any one of Examples 88-96, wherein the first dopant and the second dopants are p-type dopants.

Example 101 includes the subject matter of any one of Examples 88-100, wherein the gate dielectric layer comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 102 includes the subject matter of any one of Examples 88-100, wherein gate dielectric layer further comprises scandium and one of dysprosium, terbium, gadolinium, europium, samarium, neodymium, praseodymium, cerium, and lanthanum.

Example 103 includes the subject matter of any one of Examples 88-102, wherein the first metal comprises tungsten, cobalt, titanium, gold, aluminum, molybdenum, chromium, or nickel.

Example 104 includes the subject matter of any one of Examples 88-102, wherein the second metal comprises tungsten, cobalt, titanium, gold, aluminum, molybdenum, chromium, or nickel.

Example 105 includes the subject matter of any one of Examples 88-104, wherein the substrate comprises silicon; silicon and oxygen; or strontium, titanium, and oxygen.

Example 106 includes a method of forming a perovskite field effect transistor, the method comprising forming a channel region comprising a first perovskite material comprising a first dopant, the channel region located on a substrate or template layer; forming a source region comprising a second perovskite material comprising a second dopant; forming a drain region comprising the second perovskite material comprising the second dopant, the channel region positioned laterally between the source region and the drain region, a peak concentration of the second dopant in the source region is greater than a peak concentration of the first dopant in the channel region; forming a source contact region comprising a first metal and positioned adjacent to the source region; forming a drain contact region comprising the first metal and positioned adjacent to the drain region; forming a gate dielectric layer comprising a third perovskite material and located on the channel region; and forming a gate electrode comprising the first metal or a second metal located on the gate dielectric layer, the gate dielectric layer positioned between the gate electrode and the channel region.

Example 107 includes the subject matter of Example 106, and further including forming a fin extending upwards from a surface of the substrate, wherein the fin comprises the source region, the drain region, and the channel region, wherein the gate dielectric layer encompasses an end of the fin.

Example 108 includes the subject matter of any one of Examples 106-107, wherein the first perovskite material comprises barium, tin, and oxygen; strontium, tin, and oxygen; strontium, titanium, and oxygen; or barium, strontium, tin, and oxygen.

Example 109 includes the subject matter of any one of Examples 106-108, wherein the first dopant comprises lanthanum, neodymium, cesium, cerium, yttrium, vanadium, potassium, or cobalt.

Example 110 includes the subject matter of any one of Examples 106-109, wherein a doping concentration of the first dopant in the channel region is about 3% or less.

Example 111 includes the subject matter of any one of Examples 106-109, wherein a doping concentration of the first dopant in the channel region is in the range of about 0.1% to 3%.

Example 112 includes the subject matter of any one of Examples 106-109, wherein a doping concentration of the second dopant in the source region and the drain region is in the range of about 3% to 15%.

Example 113 includes the subject matter of any one of Examples 106-112, wherein the second perovskite material comprises barium, tin, and oxygen; strontium, tin, and oxygen; strontium, titanium, and oxygen; or barium, strontium, tin, and oxygen.

Example 114 includes the subject matter of any one of Examples 106-113, wherein the second dopant comprises lanthanum, neodymium, cesium, cerium, yttrium, vanadium, potassium, or cobalt.

Example 115 includes the subject matter of any one of Examples 106-114, wherein the first dopant is the same as the second dopant.

Example 116 includes the subject matter of any one of Examples 106-114, wherein the first dopant is different from the second dopant.

Example 117 includes the subject matter of any one of Examples 106-114, wherein the first dopant and the second dopants are n-type dopants.

Example 118 includes the subject matter of any one of Examples 106-114, wherein the first dopant and the second dopants are p-type dopants.

Example 119 includes the subject matter of any one of Examples 106-118, wherein the gate dielectric layer comprises hafnium and oxygen; silicon and oxygen; barium, tin, and oxygen; strontium, tin, and oxygen; strontium, titanium, and oxygen; lanthanum, aluminum, and oxygen; barium, hafnium, and oxygen; barium, zirconium, and oxygen; strontium, zirconium, and oxygen; strontium, hafnium, and oxygen; lanthanum, indium, and oxygen; lanthanum, scandium, and oxygen; lanthanum, lutetium, and oxygen; lanthanum, lutetium, scandium, and oxygen; or magnesium and oxygen.

Example 120 includes the subject matter of any one of Examples 106-118, wherein the gate dielectric layer comprises scandium, oxygen, and one of dysprosium, terbium, gadolinium, europium, samarium, neodymium, praseodymium, cerium, and lanthanum.

Example 121 includes the subject matter of any one of Examples 106-118, wherein the gate dielectric layer comprises barium, titanium, and oxygen; barium, zirconium, titanium, and oxygen; barium, calcium, titanium, and oxygen; barium, strontium, titanium, and oxygen; barium, calcium, titanium, zirconium, and oxygen; barium, hafnium, titanium, and oxygen; bismuth, and iron, oxygen; bismuth, lanthanum, iron, and oxygen; bismuth, iron, cobalt, and oxygen; lithium niobium, and oxygen; potassium niobium, and oxygen; gadolinium iron, and oxygen; gadolinium, lanthanum, iron, and oxygen; or hafnium zirconium, and oxygen.

Example 122 includes the subject matter of any one of Examples 116-118, wherein the gate dielectric layer comprises hafnium, oxygen, and one of lanthanum, strontium, aluminum, silicon, yttrium, gadolinium, and zirconium.

Example 123 includes the subject matter of any one of Examples 116-121, further comprising a layer positioned between the substrate and the channel region, the substrate and the source region, and the substrate and the drain region, the layer comprising a fourth perovskite material.

Example 124 includes the subject matter of Example 123, and wherein the fourth perovskite material comprises strontium, titanium, and oxygen and the substrate comprises silicon.

Example 125 includes the subject matter of Example 123, and wherein the fourth perovskite material having a dielectric constant greater than silicon dioxide.

Example 126 includes the subject matter of Example 123, and wherein the fourth perovskite material comprises strontium, ruthenium, and oxygen; strontium, barium, ruthenium, and oxygen; strontium, indium, and oxygen; lanthanum, barium, strontium, and oxygen; lanthanum, strontium, manganese, and oxygen; lanthanum, barium, cobalt, and oxygen; lanthanum, niobium, and oxygen; lanthanum, nickel, and oxygen; lanthanum, ruthenium, and oxygen; strontium, vanadium, and oxygen; strontium, cobalt, and oxygen; strontium, molybdenum, and oxygen; or yttrium, barium, copper, and oxygen.

Example 127 includes the subject matter of any one of Examples 116-125, wherein the first metal comprises tungsten, cobalt, titanium, gold, aluminum, molybdenum, chromium, or nickel.

Example 128 includes the subject matter of any one of Examples 116-126, wherein the second metal comprises tungsten, cobalt, titanium, gold, aluminum, molybdenum, chromium, or nickel.

Example 129 includes the subject matter of any one of Examples 116-127, wherein the apparatus further comprises a first spacer region positioned between the gate dielectric layer and the source contact region, a portion of the source region extending under the first spacer region; and a second spacer region positioned between the gate dielectric layer and the drain contact region, a portion of the drain region extending under the second spacer region.

Example 130 includes the subject matter of Example 129, and wherein the first spacer region and the second spacer region comprise silicon and oxygen; silicon, oxygen, and one of carbon, fluorine, and hydrogen; or silicon and nitrogen.

Example 131 includes the subject matter of any one of Examples 116-129, wherein the substrate or template layer comprises silicon; silicon and oxygen; or strontium, titanium, and oxygen.

1. An apparatus, comprising:
a substrate or template layer;
a channel region comprising a first perovskite material comprising a first dopant;
a source region comprising a second perovskite material comprising a second dopant;
a drain region comprising the second perovskite material comprising the second dopant, wherein the channel region is positioned laterally between the source region and the drain region, and wherein the source region, the drain region, and the channel region are located on the substrate or template layer, and wherein a peak concentration of the second dopant in the source region is greater than a peak concentration of the first dopant in the channel region;
a source contact region comprising a first metal and positioned adjacent to the source region;
a drain contact region comprising the first metal and positioned adjacent to the drain region;
a gate dielectric layer comprising a third perovskite material and located on the channel region; and
a gate electrode comprising the first metal or a second metal located on the gate dielectric layer, the gate dielectric layer positioned between the gate electrode and the channel region.

2. The apparatus of claim 1, further comprising a fin that extends upwards from a surface of the substrate, wherein the fin comprises the source region, the drain region, and the channel region, wherein the gate dielectric layer encompasses an end of the fin.

3. The apparatus of claim 1, wherein the first perovskite material and/or the second perovskite material comprises:
barium, tin, and oxygen;
strontium, tin, and oxygen;
strontium, titanium, and oxygen; or
barium, strontium, tin, and oxygen.

4. The apparatus of claim 1, wherein the first dopant and/or the second dopant comprises lanthanum, neodymium, cesium, cerium, yttrium, vanadium, potassium, or cobalt.

5. The apparatus of claim 1, wherein the gate dielectric layer comprises:
hafnium and oxygen;
silicon and oxygen;
barium, tin, and oxygen;
strontium, tin, and oxygen;
strontium, titanium, and oxygen;
lanthanum, aluminum, and oxygen;
barium, hafnium, and oxygen;
barium, zirconium, and oxygen;
strontium, zirconium, and oxygen;
strontium, hafnium, and oxygen;
lanthanum, indium, and oxygen;
lanthanum, scandium, and oxygen;
lanthanum, lutetium, and oxygen;
lanthanum, lutetium, scandium, and oxygen; or
magnesium and oxygen.

6. The apparatus of claim 1, wherein the gate dielectric layer comprises scandium, oxygen, and one of dysprosium, terbium, gadolinium, europium, samarium, neodymium, praseodymium, cerium, and lanthanum.

7. The apparatus of claim 1, wherein the apparatus further comprises:
an integrated circuit component comprising the channel region, the source region, the drain region, and the substrate or template layer; and
a printed circuit board, the integrated circuit component attached to the printed circuit board.

8. An apparatus, comprising:
a substrate;
one or more layers stacked vertically above and separate from the substrate, individual of the layers comprising:
a channel region comprising a first perovskite material comprising a first dopant;
a first source region comprising a second perovskite material comprising a second dopant; and
a first drain region comprising the second perovskite material comprising the second dopant, wherein the channel region is positioned laterally between the first source region and the first drain region, and wherein a peak concentration of the second dopant in the first source region is greater than a peak concentration of the first dopant in the channel region;
a second source region encompassing a portion of individual of the first source regions, the second source region comprising the second dopant;
a second drain region encompassing a portion of individual of the first drain regions, the second drain region comprising the second dopant;
a source contact region comprising a first metal and positioned adjacent to the second source region,
a drain contact region comprising the first metal and positioned adjacent to the second drain region, and
a plurality of gate regions stacked vertically with respect to the substrate, the gate regions comprising a first gate dielectric layer comprising a third perovskite material and all but the topmost first gate regions further comprising a first gate electrode encircled by the first gate dielectric layer, wherein the first gate electrodes comprise the first metal or a second metal, and wherein individual of the channel regions are positioned adjacent to two first gate regions;
wherein individual of the channel regions are positioned vertically adjacent to two gate regions.

9. The apparatus of claim 8, wherein the first perovskite material and/or the second perovskite material comprises:
barium, tin, and oxygen;
strontium, tin, and oxygen;
strontium, titanium, and oxygen; or
barium, strontium, tin, and oxygen.

10. The apparatus of claim 8, wherein the first dopant and/or the second dopant comprises lanthanum, neodymium, cesium, cerium, yttrium, vanadium, potassium, or cobalt.

11. The apparatus of claim 8, wherein the layers are first layers, the source contact region is a first source contact region, the drain contact region is a first drain contact region, the gate regions are first gate regions, the apparatus further comprising:
one or more second layers stacked vertically above and separate from the substrate, individual of the second layers comprising:
a channel region comprising a fourth perovskite material comprising a third dopant;
a first source region comprising a fifth perovskite material comprising a fourth dopant; and
a first drain region comprising the fifth perovskite material comprising the fourth dopant, wherein the channel region is positioned laterally between the first source region and the first drain region, and wherein a peak concentration of the fourth dopant in the first source region is greater than a peak concentration of the second dopant in the channel region;
a third source region encompassing a portion of individual of the first source regions of the second layers, the third source region comprising the fourth dopant;
a third drain region encompassing a portion of individual of the first drain regions of the second layers, the third drain region comprising the fourth dopant;
a second source contact region comprising the first metal and positioned adjacent to the third source region;
a second drain contact region comprising the first metal and positioned adjacent to the third drain region;
a middle dielectric layer positioned between the first layers and the second layers; and
a plurality of second gate regions stacked vertically with respect to the substrate, the second gate regions comprising a second gate dielectric layer comprising a sixth perovskite material and all but the topmost second gate regions further comprising a second gate electrode encircled by the second gate dielectric layer, wherein the second gate electrodes comprise the first metal or the second metal, wherein second first gate electrodes comprise a first metal, and wherein individual of the channel regions of the second layers are positioned adjacent to two second gate regions;
wherein individual of the channel regions of the second layers are positioned vertically adjacent to two second gate regions.

12. The apparatus of claim 11, wherein the third and fourth dopants are the same.

13. The apparatus of claim 11, wherein the fourth perovskite material and the fifth perovskite material comprises:
barium, tin, and oxygen;
strontium, tin, and oxygen;
strontium, titanium, and oxygen; or
barium, strontium, tin, and oxygen.

14. The apparatus of claim 11, wherein the sixth perovskite material comprises:
hafnium and oxygen;
silicon and oxygen;
barium, tin, and oxygen;
strontium, tin, and oxygen;
strontium, titanium, and oxygen;
lanthanum, aluminum, and oxygen;
barium, hafnium, and oxygen;
barium, zirconium, and oxygen;
strontium, zirconium, and oxygen;
strontium, hafnium, and oxygen;
lanthanum, indium, and oxygen;
lanthanum, scandium, and oxygen;
lanthanum, lutetium, and oxygen;
lanthanum, lutetium, scandium, and oxygen; or
magnesium and oxygen.

15. The apparatus of claim 11, wherein the sixth dielectric material comprises scandium, oxygen, and one of dysprosium, terbium, gadolinium, europium, samarium, neodymium, praseodymium, cerium, and lanthanum.

16. The apparatus of claim 11, wherein the apparatus is an integrated circuit component.

17. The apparatus of claim 16, further comprising a printed circuit board, the integrated circuit component attached to the printed circuit board.

18. A method of forming a perovskite field effect transistor, the method comprising:
forming a channel region comprising a first perovskite material comprising a first dopant, the channel region located on a substrate or template layer;
forming a source region comprising a second perovskite material comprising a second dopant;
forming a drain region comprising the second perovskite material comprising the second dopant, the channel region positioned laterally between the source region and the drain region, a peak concentration of the second dopant in the source region is greater than a peak concentration of the first dopant in the channel region;
forming a gate dielectric layer comprising a third perovskite material and located on the channel region;
forming a gate electrode comprising a first metal located on the gate dielectric layer, the gate dielectric layer positioned between the gate electrode and the channel region;
forming a source contact region comprising the first metal or a second metal and positioned adjacent to the source region; and
forming a drain contact region comprising the first metal or the second metal and positioned adjacent to the drain region.

19. The method of claim 18,
wherein the first perovskite material and/or the second perovskite material comprises:
barium, tin, and oxygen;
strontium, tin, and oxygen;
strontium, titanium, and oxygen; or
barium, strontium, tin, and oxygen;
wherein the first dopant and/or the second dopant comprises lanthanum, neodymium, cesium, cerium, yttrium, vanadium, potassium, or cobalt.

20. The method of claim 18, wherein the gate dielectric layer comprises:
hafnium and oxygen;
silicon and oxygen;
barium, tin, and oxygen;
strontium, tin, and oxygen;
strontium, titanium, and oxygen;
lanthanum, aluminum, and oxygen;
barium, hafnium, and oxygen;
barium, zirconium, and oxygen;
strontium, zirconium, and oxygen;
strontium, hafnium, and oxygen;
lanthanum, indium, and oxygen;
lanthanum, scandium, and oxygen;
lanthanum, lutetium, and oxygen;
lanthanum, lutetium, scandium, and oxygen; or
magnesium and oxygen.
